(19) United States
(12) Patent Application Publication
(10) Pub. No.: US 2016/0013434 A1
(43) Pub. Date: Jan. 14, 2016

(54) Semiconducting Layer Production Process

(71) Applicant: ISIS INNOVATION LIMITED, Oxfordshire (GB)

(72) Inventors: Henry James SNAITH, Oxford (GB); Edward James Williams CROSSLAND, Oxford (GB); Nakita NOEL, Oxford (GB); Varun SIVARAM, Oxford (GB); Tomas LEIJTENS, Oxford (GB)

(21) Appl. No.: 14/771,584

(22) PCT Filed: Feb. 28, 2014
(86) PCT No.: PCT/GB2014/050599

§ 371 Date: Aug. 31, 2015

(30) Foreign Application Priority Data
Mar. 1, 2013 (GB) 1303682.7
Dec. 10, 2013 (GB) 1321820.1

(51) Int. Cl. H01L 51/42; H01L 51/00; H01G 9/20

(52) U.S. Cl. CPC H01L 51/4226; H01G 9/2031; H01G 9/204; H01L 51/4233; H01L 51/0003

(57) ABSTRACT

The invention provides a process for producing a layer of a semiconductor material, wherein the process comprises: a) disposing on a substrate: i) a plurality of particles of a semiconductor material, ii) a binder, wherein the binder is a molecular compound comprising at least one metal atom or metalloid atom, and iii) a solvent; and b) removing the solvent. The invention also provides a layer of semiconductor material obtainable by this process. In a preferred embodiment, the particles of a semiconductor material comprise mesoporous particles of the semiconductor material or mesoporous single crystals of the semiconductor material. The invention provides a process for producing a compact layer of a semiconductor material, wherein the process comprises: disposing on a substrate i) a solvent, and ii) a molecular compound comprising at least one metal or metalloid atom and one or more groups of formula OR, wherein each R is the same or different and is an unsubstituted or substituted C₁-C₈ hydrocarbyl group, and wherein two or more R groups may be bonded to each other; and b) removing the solvent. The invention also provides a compact layer of a semiconductor material obtainable by this process. These processes can be effectively performed at temperatures of less than 300° C. Further provided are semiconductor devices comprising either a layer of a semiconductor material or a compact layer of a semiconductor material obtainable by the processes of the invention. The invention also provides a process for producing a semiconductor device.

### FIELD OF THE INVENTION

The invention relates to a process for producing a layer of a semiconductor material processed at moderate temperatures. The invention also relates to a process for producing a compact layer of a semiconductor material processed at moderate temperatures. Furthermore, the invention relates to devices comprising layers obtainable by these processes.

The invention also provides a compact layer for a semiconductor device and semiconductor devices comprising said compact layer.

### BACKGROUND OF THE INVENTION

It is rare to find a contemporary electronic device which does not have as an integral component a semiconductor material in some form or another. In particular, layers of semiconductor materials are near ubiquitous in electronics. These layers may be mesoporous layers or compact layers. Compact layers are typically dense nano- or microcrystalline films.

Increasingly, layers of a semiconductor material displaying a high surface area are finding important applications. For example, mesoporous ceramics and semiconductors promise advanced solutions to low-cost solar power technologies, solar fuels, (photo)catalysis and electrical energy storage. However, in many cases, it can be difficult to produce a high surface area layer of a semiconductor material which also maintains good electronic properties without resorting to the use of high temperature sintering. In the case of mesoporous (high surface area) semiconductor layers produced from nanocrystalline semiconductor material, the electronic properties of the layers suffer due to the large number of junctions between adjacent nanocrystals. High temperature sintering is often used to improve contacts between adjacent nanocrystals in such layers. Many semiconductor devices will be degraded by high temperature treatment, particularly in the case of devices consisting of multiple layers, for instance multi-junction solar cells, and devices based on polymeric substrates. It is therefore desirable to provide a process for producing layers of semiconductor material which demonstrate both high surface area and good electronic properties without the use of sintering at a high temperature.

Current state-of-the-art solution-processable high surface area semiconductor layers are fabricated from thermally-sintered pre-formed nanocrystals (Yella, A. et al. “Porphyrin-sensitized solar cells with cobalt (ii/iii) based redox electrolyte exceed 12 percent efficiency”, Science 334, 629-634 (2011); O'Regan, B. & Gratzel, M. “A low-cost, high-efficiency solar cell based on dye-sensitized colloidal TiO₂, Nature 353, 737 (1991); Gratzel, M. “Photoelectrochemical cells”, Nature 414, 338 (2001); Lee, M. M., Teuscher, J., Miyasaka, T., Murakami, T. N. & Snaith, H. J. “Efficient hybrid solar cells based on meso-superstructured organometal halide perovskites”, Science 338, 643-647 (2012)).

O'Regan et al. (“Influence of the TiCl₄ treatment of nanocrystalline TiO₂ films in dye-sensitized solar cells. 2. Charge density, band edge shifts, and quantification of recombination losses at short circuit”, J. Phys. Chem. C 111, 14001 (2007)) discloses a process comprising treating a TiO₂ layer with TiCl₄ by soaking the layer in a TiCl₄ solution and then washing. This step occurs between two steps in which the layer is heated to above 500° C.

A low temperature process is proposed in Jiang et al. (“Low temperature processing of solid-state dye sensitized solar cells”, Applied Physics Letters 100, 113901 (2012)) where a binder-free paste of nanocrystalline TiO₂ is formed in tertbutanol and spin-coated onto a substrate.

A further low temperature process is given in Miyasaka (“Towards printable sensitized mesoscopic solar cells: light-harvesting management with thin TiO₂ films”, J. Phys. Chem. Lett. 2, 262-269 (2011)). Here, a high viscosity binder-free paste is formed by dispersing nanocrystalline TiO₂ in a water-alcohol mixture in the presence of a TiOₓ aqueous sol.

Compact layers of a semiconductor material are also of considerable importance in semiconductor devices. In particular, lightweight and mechanically flexible photovoltaic devices are of an increasing interest and demand, mainly due to their ease of integration and versatile functionality. Potential applications range from portable electronic devices, electronic textiles, synthetic skin, robotics to aerospace technology. Commercially attractive reel-to-reel processing is contingent on solution-based, low temperature technology in order to fabricate devices on transparent, flexible substrates, such as polyethylene terephthalate (PET) and polyethylene naphthalate (PFN) which may degrade at higher temperatures. Additionally, low temperature fabrication allows for the possibility of new multi-junction device architectures, as has been a successful route to higher efficiencies for organic photovoltaics. A recently emerged class of solution-processed hybrid solar cells are based on organometal trihalide perovskite absorbers, which exhibit exceptional performance and are already approaching the performances of the best thin film technologies. This cell type has already been shown to work without high temperature sintering steps for the mesoporous scaffold (J. M. Ball et al., Energy & Environmental Science, 2013, 6, 1739), closing the gap to achieving fully low-temperature solution-based perovskite devices. However, both planar heterojunction and mesosuperstructured solar cells still require sintering of the compact layer (at temperatures of up to 500° C.), where the compact layer works as a selective contact for electron collection at the anode. Forming a dense and pinhole-free compact layer at the anode is an effective way to prevent recombination by electron leakage from anode (e.g. FTO) to hole-transporter or to the photoactive layer (e.g. a perovskite film) itself. Titanium dioxide is the most commonly and successfully employed material to selectively transport electrons to FTO contacts in dye-sensitized solar cells (DSSCs). Typically, this compact layer is prepared by spin-coating or spray pyrolysis of a solution of TiO₂ precursor with subsequent sintering at 500° C. in order to transform the amorphous oxide layer into the crystalline form (anatase), which provides good charge transport properties. The problem of high temperature processing of TiO₂ blocking layers has been addressed previously in DSSCs. Atomic layer deposition, microwave sintering and inductively coupled plasma (ICP)-assisted DC magnetron sputtering have been used to process compact TiO₂ hole-blocking layers. However, the results generally yielded lower efficiency in DSSCs than high-temperature processed TiO₂. Thus, it is an object of the present invention to provide a low temperature process for producing compact layers of a semiconductor which may, for instance, be used as hole blocking layers in semiconductor devices.

### SUMMARY OF THE INVENTION

The present inventors have developed processes for producing layers of a semiconductor material. They have found that it is possible to produce layers of a semiconductor material formed from particles of the semiconductor material which can show both high surface area and good electronic properties, particularly regarding electron transport properties. This process makes use of a binder which reduces the disruptive effect of inter-particle junctions. The use of these binder compounds mitigates the need for high temperature sintering, thus advantageously allowing for the production of high performance optoelectronic devices at relatively low temperatures.

It has been shown that the same process may be used to produce compact layers of a semiconductor material, which compact layers show good electron transport properties and allow efficient semiconductor device operation. In particular, the inventors have also developed a low temperature fabrication (for instance less than 150° C.) of a compact layer of a semiconductor material composed of highly crystalline small nanoparticles of a semiconductor (for instance anatase TiO₂ with an average particle size of less than 5 nm) dispersed in a solvent with an addition of a binder, for instance titanium diisopropoxide bis(acetylacetonate) (TiAcAc). This approach results in a dense semiconductor layer with 100 fold higher conductivity than the known high temperature routes. The ensuing all-low-temperature MSSC outperform the previous state of the art, delivering a maximum full sun power conversion efficiency of 15.8%.

Accordingly, the invention provides a process for producing a layer of a semiconductor material, the process comprising:
a) disposing on a substrate
   i) a plurality of particles of a semiconductor material,
   ii) a binder, wherein the binder is a molecular compound comprising at least one metal atom or metalloid atom, and
   iii) a solvent; and
b) removing the solvent.

This process can be effectively performed at relatively low temperatures, for instance at temperatures of less than 300° C. The invention also provides a layer of semiconductor material obtainable by this process.

The particles of a semiconductor material may comprise mesoporous particles of a semiconductor material. Preferably the particles of a semiconductor material comprise mesoporous single crystals of the semiconductor material.

For the production of compact layers of a semiconductor material, the particles of a semiconductor material typically comprise nanoparticles of the semiconductor material.

Compact layers are also important for the construction of semiconductor devices. The inventors have found that these can also be produced at low temperatures by using a molecular compound comprising a metal or metalloid atom and one or more groups of formula OR, wherein each R is the same or different and is an unsubstituted or substituted C₁-C₈ hydrocarbyl group, and wherein two or more R groups may be bonded to each other.

Accordingly, the invention provides a process for producing a compact layer of a semiconductor material, wherein the process comprises:

a) disposing on a substrate
i) a solvent, and
ii) a molecular compound comprising at least one metal or metalloid atom and one or more groups of formula OR, wherein each R is the same or different and is an unsubstituted or substituted C₁-C₈ hydrocarbyl group, and wherein two or more R groups may be bonded to each other; and

b) removing the solvent.

Again, this process can be effectively performed at relatively low temperatures, for instance at temperatures of less than 300° C. The invention also provides a compact layer of a semiconductor material obtainable by this process.

Further provided are semiconductor devices comprising either a layer of a semiconductor material or a compact layer of a semiconductor material obtainable by a process of the invention.

The invention also provides a compact layer for a semiconductor device. Thus, the invention provides a compact layer for a semiconductor device, which compact layer comprises a plurality of crystalline particles of a semiconductor material bound together by a decomposition product of a binder, wherein the binder is a molecular compound comprising at least one metal atom or metalloid atom. The invention also provides a semiconductor device comprising the compact layer according to the invention.

The invention also provides a process for producing a semiconductor device which comprises the process of the invention for producing a layer of a semiconductor material.

Accordingly, the invention provides a process for producing a semiconductor device comprising a layer of a semiconductor material, wherein the process comprises producing said layer of a semiconductor material by:

p) disposing on a substrate
i) a plurality of particles of a semiconductor material,
ii) a binder, wherein the binder is a molecular compound comprising at least one metal atom or metalloid atom, and
iii) a solvent; and

q) removing the solvent.

The invention also provides a process for producing a semiconductor device which comprises the process of the invention for producing a compact layer of a semiconductor material.

Accordingly the invention provides a process for producing a semiconductor device comprising a compact layer of a semiconductor material, wherein the process comprises producing said compact layer of a semiconductor material by:

p) disposing on a substrate
i) a molecular compound comprising at least one metal or metalloid atom and one or more groups of formula OR, wherein each R is the same or different and is an unsubstituted or substituted C₁-C₈ hydrocarbyl group, and wherein two or more R groups may be bonded to each other; and
ii) a solvent; and

q) removing the solvent.

### BRIEF DESCRIPTION OF THE FIGURES

FIG. 1 shows SEM surface images at high and low magnification of a film of TiO₂ single crystals (MSCs) deposited with or without the presence of a TiAcAc (titanium di-isopropoxide bis(acetylacetonate)) binder. (a,b) shows a film produced without the use of a binder. (c,d) shows a film produced with 15 mol % of the TiAcAc binder.

FIG. 2 shows: (a) a schematic of a solid-state dye-sensitized solar cell device based on sub-150° C. processed TiO₂ MSCs; (b) an SEM cross-sectional image of an MSC ensemble deposited without a binder agent; and (c) device performance parameters based on D102 dye or CH₃NH₃PbI₂Cl perovskite sensitizer.

FIG. 3 shows transient photocurrent short circuit current decay lifetimes for D102-sensitized devices based on 500° C. sintered nanoparticles (Dyesol 18NR-T, 20 nm average particle size) and 150° C. dried TiO₂ MSCs deposited from an ethanol dispersion containing MSCs and 15 mol % TiAcAc binder.

FIG. 4 shows performance parameters (short circuit current density, power conversion efficiency, open circuit voltage and fill factor) for solid-state dye-sensitized solar cells based on TiO₂ MSCs dried at 150° C. as a function of amount of TiAcAc binder present in the coating dispersion.

FIG. 5 shows (a) Cross-sectional image of 3.54 weight % TiO₂ nanoparticles (NPs) in ethanol solution spin-coated on glass, dry film thickness: 100-120 nm; (b) top surface image of lt-TiO₂; (c) X-ray diffraction spectrum of TiO₂ nanoparticles powder sample.

FIG. 6 shows current-voltage characteristics of the best performing solar cells made with amorphous (TiOₓ), high-temperature (ht-TiO₂) and low-temperature (lt-TiO₂) processed compact layer.

FIG. 7 shows photovoltaic parameters extracted from current-voltage measurements of series of solar cells with different compact layers.

FIG. 8 shows open circuit voltage against differential capacitance for devices comprising different TiO₂ compact layers.

FIG. 9 shows short circuit current decay lifetime at different light intensities for devices comprising an ht-TiO₂ compact layer or different lt-TiO₂ compact layers.

### DETAILED DESCRIPTION OF THE INVENTION

The inventors have shown that adding a binder which is a molecular compound comprising at least one metal atom or metalloid atom (for instance TiAcAc) to particles of a semiconductor material (for instance mesoporous single crystals of TiO₂) can greatly enhance the adhesive properties of the film produced and enhance the operation of dye-sensitized solar cells (which require a mesoporous layer of a semiconductor material) when processed at low temperature. The same process can be used to produce compact layers of a semiconductor material by using nanoparticles of the semiconductor material.

The invention provides a process for producing a layer of a semiconductor material, wherein the process comprises:
a) disposing on a substrate
   i) a plurality of particles of a semiconductor material,
   ii) a binder, wherein the binder is a molecular compound comprising at least one metal atom or metalloid atom, and
   iii) a solvent; and
b) removing the solvent.

Parts (a) and (b) of the process of the invention may be performed simultaneously or one after the other. Usually, part (a) will be performed first, and then part (b) will be performed second.

The term “disposing”, as used herein, refers to the placing or making available of a component in a specified location, in this case on, in or near a surface of a substrate. The disposition of a component onto a substrate does not necessarily imply that the component is disposed directly onto the substrate, there may be an intervening layer or intervening layers (between the substrate and the layer disposed or being disposed). Typically, the disposing of a component will involve the deposition of the component on a surface of the substrate. The disposition may be performed on more than one surface of the substrate. The three components given in part (a) of the process of the invention may be disposed on the substrate together or independently, and in any order if deposited independently. The disposition of a component, composition, solution or dispersion on the substrate may occur by any appropriate process. For instance by spin-coating, spray-coating, slot-die-coating, screen-printing, doctor blade coating, Gravure printing, inkjet printing, thermal evaporation, sputter coating, or any other vapour deposition. Preferably the disposition of a component occurs by spin-coating, slot-die-coating or spray coating.

Typically, the process according to the invention is a process for producing a mesoporous or high surface area layer of a semiconductor material. Preferably, the process according to the invention is a process for producing a mesoporous layer of a semiconductor material.

The process for producing a layer of semiconductor material according to the invention is typically carried out at a temperature less than or equal to 500° C., less than or equal to 400° C., or preferably less than or equal to 300° C. The process can even be carried out at a temperature less than or equal to 200° C. or less than or equal to 150° C. Low processing temperatures allow the process of the invention to be carried out in the presence of materials such as plastics and other organic components which would deform, oxidize, degrade or decompose at higher temperatures. Relatively low processing temperatures also allow the formation of multi-junction semiconductor devices which have the potential to degrade under more severe temperatures. This includes processing a semiconducting layer or device on top of a conventional crystalline silicon p-n junction solar cell, or a copper indium gallium diselenide (CIGS).

Typically, the binder is a molecular compound comprising at least one metal atom or metalloid atom and one or more atoms selected from O, S, Se and Te.

In one embodiment, the disposition of the components in part (a) of the process on the substrate comprises disposing on the substrate: 1) a composition comprising the solvent and the binder; and 2) the plurality of particles of a semiconductor material. These may be disposed either simultaneously, or one after the other. Typically, the binder will be dissolved in the solvent, but it may be dispersed or suspended in the solvent. Often, the plurality of particles of a semiconductor material are disposed on the surface first, and then the composition comprising the solvent and the binder is disposed on the surface second.

In another embodiment, the disposition of the components in part (a) of the process on the substrate comprises disposing on the substrate: 1) a composition comprising the solvent and a plurality of particles of a semiconductor material; and 2) the binder. These may be disposed either simultaneously, or one after the other. Typically, the plurality of particles of a semiconductor material will be dispersed in the solvent, but may be also be suspended in the solvent.

In another embodiment, the disposition of the components in part (a) of the process on the substrate comprises disposing on the substrate: 1) a composition comprising the binder and the plurality of particles of a semiconductor material; 2) and the solvent. These may be disposed either simultaneously, or one after the other. Typically, the binder and the plurality of particles of a semiconductor material will be disposed as a mixture of the two components.

Preferably, the disposition of the components in part (a) of the process the substrate comprises disposing on the substrate a composition comprising the solvent, the binder and the plurality of particles of a semiconductor material. Typically the composition will be a homogeneous composition in which the binder is dissolved in the solvent and the plurality of particles of a semiconductor material will be dispersed or suspended in the solvent.

In one embodiment, the process according to the invention comprises:
a) disposing on the substrate
   i) a first composition comprising the plurality of particles of a semiconductor material, and
   ii) a second composition comprising the binder,
wherein at least one of the first and the second composition also comprises the solvent; and
b) removing the solvent.

Here, the first composition typically further comprises the solvent which is a first solvent, and the second composition further comprises a second solvent, wherein the first and second solvents are the same or different and where part (b) comprises removing the first and second solvents. Preferably, the first composition comprises the plurality of particles of a semiconductor material dispersed in the first solvent, and the second composition comprises the binder dissolved in the second solvent.

The process of the invention may comprise disposing on the substrate a composition comprising the solvent, the binder and the plurality of particles of a semiconductor material; and removing the solvent; preferably wherein the plurality of particles of a semiconductor material are suspended or dispersed in the solvent and the binder is dissolved in the solvent.

The solvent may be any solvent which is appropriate for use in the process of the invention. The solvent will typically be a liquid at standard ambient temperature and pressure (25° C. and 100 kPa). The solvent will typically comprise an organic solvent or water. The solvent may consist of a single solvent, a single solvent together with a trace (less than 1 wt %) amount of another solvent, or a mixture of two or more solvents.

The term “semiconductor material”, as used herein, refers to a material with electrical conductivity intermediate in magnitude between that of a conductor and an insulator. Typically, a semiconductor material is a material that has a conductivity of from 103 to 10⁻⁸ Scm⁻¹. Standard techniques such as a 4-point probe conductivity measurement may be used to measure conductivity. Examples of semiconductor materials include an oxide or chalcogenide of a metal or metalloid element; a group IV compound; a compound comprising a group III element and a group V element; a compound comprising a group II element and a group VI element; a compound comprising a group I element and a group VII element; a compound comprising a group IV element and a group VI element; a compound comprising a group V element and a group VI element; a compound comprising a group II element and a group V element; a ternary or quaternary compound semiconductor; a perovskite semiconductor or an organic semiconductor. Typical examples of semiconductor materials include oxides of titanium, niobium, tin, zinc, cadmium, copper or lead; chalcogenides of antimony or bismuth; copper zinc tin sulphide; copper zinc tin selenide, copper zinc tin selenide sulphide, copper indium gallium selenide; and copper indium gallium diselenide. Further examples are group IV compound semiconductors (e.g. silicon carbide); group III-V semiconductors (e.g. gallium arsenide); group II-VI semiconductors (e.g. cadmium selenide); group I-VII semiconductors (e.g. cuprous chloride); group IV-VI semiconductors (e.g. lead selenide); group V-VI semiconductors (e.g. bismuth telluride); and group II-V semiconductors (e.g. cadmium arsenide); ternary or quaternary semiconductors (e.g. copper indium selenide, copper indium gallium diselenide, or copper zinc tin sulphide); perovskite semiconductor materials (e.g. CH₃NH₃PbI₃ and CH₃NH₃PbI₂Cl); and organic semiconductor materials (e.g. conjugated polymeric compounds including polymers such as polyacetylenes, polyphenylenes and polythiophenes). Examples of organic semiconductors include poly(3,4-ethylenedioxythiophene), 2,2-7,7-tetrakis-N,N-di-p-methoxyphenylamine-9,9-spirobifluorene (spiro-OMeTAD) and conjugated organic polymers such as polyacetylenes, polyphenylenes, polythiophenes or polyanilines. Examples of materials which are not semiconductor materials include, for instance elemental metals, which are of course conductors, and electrical insulators or dielectrics such as silica or calcite.

Additional components may be present during the process of the invention. In particular, a plurality of particles of a second (and optionally further) semiconductor material may be present.

The term “oxide”, as used herein, refers to a compound comprising at least one oxide ion (i.e. O²⁻) or divalent oxygen atom. It is to be understood that the terms “metal oxide” and “an oxide of a metal element” used herein encompass both oxides comprising one metal, and also mixed-metal oxides. For the avoidance of doubt, a mixed-metal oxide refers to a single oxide compound comprising more than one metal element. Examples of mixed-metal oxides include zinc tin oxide and indium tin oxide. Similarly, it is to be understood that the terms “metalloid oxide” and “an oxide of a metalloid element” used herein encompass oxides comprising one metalloid element and also mixed-metalloid oxides. For the avoidance of doubt, a mixed-metalloid oxide refers to a single oxide compound comprising more than one metalloid element.

The tem “chalcogenide”, used herein, refers to a compound comprising at least one of a sulphide, selenide or telluride ion (i.e. S²⁻, Se²⁻, or Te²⁻) or a divalent sulphur, selenium or tellurium atom. It is to be understood that the terms “metal chalcogenide” and “a chalcogenide of a metal element” encompass chalcogenides comprising one metal and also mixed-metal chalcogenides. For the avoidance of doubt, a mixed-metal chalcogenide refers to a single chalcogenide compound comprising more than one metal element. Similarly, it is to be understood that the terms “metalloid chalcogenide” and “a chalcogenide of a metalloid element” used herein encompass chalcogenides comprising one metalloid and also mixed-metalloid chalcogenides. For the avoidance of doubt, a mixed-metalloid chalcogenide refers to a single chalcogenide compound comprising more than one metalloid element.

Usually, the semiconductor material comprises an oxide or chalcogenide of a metal or metalloid element. Typically, the semiconductor material consists of an oxide or chalcogenide of a metal or metalloid element. More typically, the semiconductor material comprises an oxide of titanium, niobium, tin, zinc, cadmium, copper or lead or any combination thereof; or a chalcogenide of antimony, bismuth or cadmium or any combination thereof. For instance the semiconductor material may comprise zinc tin oxide; copper zinc tin sulphide; copper indium gallium selenide, or copper indium gallium diselenide. Usually, the semiconductor material comprises an oxide of a metal or metalloid element, for instance, an oxide of titanium, niobium, tin, zinc, cadmium, copper or lead or any combination thereof. Typically, it comprises titanium dioxide. The semiconductor material may consist essentially of titanium dioxide. In one embodiment, the semiconductor material consists of titanium dioxide. Titanium dioxide may also be referred to as titania.

In one embodiment the semiconductor material may be a doped semiconductor, where an impurity element is present at a concentration ranging between 0.01 to 40%. If the impurity element acts as an electron donor, then the semiconductor material will be doped to become n-type, if the impurity element acts as an electron acceptor, then the semiconductor material will be doped to become p-type. Examples of impurity elements which will dope TiO₂ to become n-type are niobium, vanadium and manganese. Examples of impurity elements which will dope TiO₂ to become p-type are magnesium, aluminium. It is noted that for metal oxides doped with impurity metalloid elements which substitute the primary metalloid element, if the valency of the dopant is larger than the valency of the primary metalloid element then the metal oxide will be n-type doped, if the valency of the dopant metalloid element is lower than that of the primary metalloid element then the metal oxide will be p-type doped. Any of the above mentioned elements can be used to dope any of the above mentioned semiconductor materials to different levels of efficacy and effect.

The term “molecular compound”, as used herein, refers to an electrically neutral molecule comprising two or more atoms which are bound to each other by bonds which are substantially covalent in character. “Substantially covalent in character” is understood to mean that electrons are shared to some extent between the two atoms in the bond. This may occur when the two atoms have similar electronegativities. In a solution of a molecular compound, individual molecules will most often be solvated individually, although occasionally molecules may be solvated as dimers or trimers. Molecular compounds have individual stability. This is in contrast to other compounds such as some metal oxides which do not generally exist as isolated molecules in solution, but as part of, for example, an extended crystal structure.

The term “metal atom”, as used herein, refers to an atom of a metallic element. Metallic elements are those which have a delocalised band of electrons. Examples of metals include Li, Na, K, Rb, Cs, Mg, Ca, Sr, Ba, Sc, Y, Lu, Ti, Zr, Hf, V, Nb, Ta, Cr, Mo, W, Mn, Re, Fe, Ru, Os, Co, Rh, Ir, Ni, Pd, Pt, Cu, Ag, Au, Zn, Cd, Hg, Al, Ga, In, Tl, Sn, Pb, and Bi. Typically, the metal atoms in the binder present in the process of the invention are selected those in groups 3 to 12 of the periodic table of the elements and Al, Ga, In, Tl, Sn, Pb and Bi.

The term “metalloid atom”, as used herein, refers to an atom of an element which is a metalloid. Metalloid elements are those which have properties which are intermediate between those of metals and non-metals. Typically, the metalloids are taken to include B, Si, Ge, As, Sb and Te.

The plurality of particles of the semiconductor material used in the process of the present invention typically comprises more than two such particles, and generally comprises a large number of such particles.

The term “particle of a semiconductor material”, as used herein, refers to an isolated volume of a semiconductor material. The term “particle” takes its usual meaning. Typically, the particles of a semiconductor material will be microscopic in size. The particles may comprise one or more types of a semiconductor material. The particles may also comprise material which is not semiconducting. The size of each particle may be from 1 nm to 1 mm, from 10 nm to 100 μm, or from 20 nm to 10 μm. The particles are preferably from 100 to 500 nm, although the preferred size will be dependant on the nature of the particles and the materials of which the particles are composed. The particles may all be the same size or may all be different sizes. Each of the particles may be of any shape. They may be regular or irregular, spheroidal or angular, oblate or prolate.

The term “particle size”, as used herein, defines the size of the particles. For spherical particles the size is equal to the diameter of the particle. For non-spherical particles, the particle size is equal to the diameter of a sphere whose volume is equal to the volume of the non-spherical particle.

The layer of a semiconductor material produced by the process of the invention may be of any thickness. Typically, the layer will have a thickness of from 10 nm to 10 μm, from 100 to 5 μm or from 500 nm to 3 μm. In some cases, the thickness of the layer will be around 1.8 μm (e.g. from 1.5 μm to 2.5 μm). In order to control the thickness of the layer, typically the amount of particles of a semiconductor material may be chosen to give a certain thickness or the disposition of a composition may be stopped when a layer of a desired thickness is formed.

If the layer is a compact layer of a semiconductor material, the layer usually has a thickness of from 5 to 500 nm. The compact layer may have a thickness of from 20 to 200 Typically, the compact layer will have a thickness of from 30 to 150 nm or 30 to 100 The thickness of the layer of a semiconductor material produced by a process according to the invention may be controlled by varying the amount of semiconductor material disposed on the substrate. This may be done by any method, including varying the amount of the composition comprising the particles of the semiconductor material disposed on the substrate, or by varying the concentration of the particles of the semiconductor material in the composition disposed on the substrate.

In the process of the invention, the amounts of each of the components disposed on the substrate may be any amount suitable for the process. Typically, the amount of the plurality of particles of a semiconductor material will be from 1 to 50 wt %, from 5 to 35 wt %, from 5 to 20 wt %, from 8 to 20 wt % or from 8 to 12 wt %. Typically the amount of the binder is from 1 to 80 mol %, from 5 to 60 mol %, from 5 to 40 mol %, from 8 to 20 mol % or from 10 to 20 mol % relative to the amount of the semiconductor material. These ranges of amounts of the two components may be combined in any way. Typically, the amount of the plurality of particles of a semiconductor material is from 1 to 50 wt %, and the amount of the binder is from 1 to 80 mol % relative to the amount of the semiconductor material. Preferably, in one embodiment, the amount of the plurality of particles of a semiconductor material is from 5 to 20 wt %, and the amount of the binder is from 5 to 40 mol % relative to the amount of the semiconductor material. Preferably, the amount of binder is around 15 mol % (e.g. from 13 to 17 mol %) relative to the amount of the semiconductor material. The term “relative to the amount of the semiconductor material” means a molar percentage relative to the number of moles of the metal or metalloid elements in the semiconductor material. If no metal or metalloid element is present in the semiconductor material, then the mol % is relative to the number of moles of the semiconductor material based on the empirical formula of the semiconductor material. For example, if the semiconductor material is titanium dioxide, the amount of the binder is relative to the amount of TiO₂.

If the process is a process for producing a compact layer, the amount of the particles of the semiconductor material may be lower. For instance, the amount of the plurality of particles of a semiconductor material present may be from 0.05 to 20 wt %. In some embodiments, the amount of the plurality of particles of a semiconductor material present is from 0.1 to 5 wt %. Thus, the amount of the plurality of particles of a semiconductor material present may be from 0.05 to 20 wt %, and the amount of the binder may be from 5 to 40 relative to the amount of the semiconductor material. The term “relative to the amount of the semiconductor material” means a molar percentage relative to the number of moles of the metal or metalloid elements in the semiconductor material. If no metal or metalloid element is present in the semiconductor material, then the mol % is relative to the number of moles of the semiconductor material based on the empirical formula of the semiconductor material.

The quantity “wt %”, as used herein, refers to weight percentage and is measured as the percentage by weight of the component as a fraction of the total mass of the three components in the process of the invention, i.e. the solvent, the binder and the plurality of particle of a semiconductor material. For example, if there is 60 g of solvent, 30 g of particles of a semiconductor material and 10 g of binder present, the wt % of the particles is 30 wt %.

The quantity “mol %”, as used herein, refers to molar percentage and is measured as the percentage by amount of the component as a fraction of the amount of the component (or components) to which the molar percentage is relative.

The substrate upon which the layer of semiconductor material is produced by the process of the invention may be any substrate. The substrate may be composed of a single material or a mixture of materials, and may be homogeneous or inhomogeneous, planar or curved, smooth or rough. The substrate may be conducting, semiconducting or insulating.

In one embodiment, the substrate will be a substrate suitable for use in a semiconductor device. The term “substrate suitable for use in a semiconductor device”, as used herein, refers to any substrate that may be used as a material within a semiconductor device without preventing the functioning of the device. The substrate suitable for use in a semiconductor device may be a component which serves a functional purpose within a semiconductor device. The substrate may be a layer of an electrode material, an insulating layer, an electron transporter layer, a hole transporter layer or a semiconducting layer. In one embodiment, the substrate comprises an electrode material or a compact layer of a semiconductor material. The term “electrode material”, as used herein, refers to an electrically conducting material which may be in contact with another material such as a semiconductor material or an electrolyte. Electrode materials may comprise a range of materials. In particular the substrate may be an electrode material comprising a metal or mixture of metals (e.g. Al, Steel, Mo, Cu, Ag, Au or Pt, or a metal selected from any of those described above), graphite or a transparent conducting oxide (e.g. ITO (indium tin oxide), FTO (fluorine doped tin oxide) or AZO (aluminium doped zinc oxide)). An electrode may comprise nanowires of an electrode material, for instance a metal. The substrate may also be, in particular, a compact layer of a semiconductor material. The term “semiconductor material” is as defined above and the term “compact layer”, as used herein, refers to a layer of substantially a single thickness of a material wherein the space occupied by the layer consists essentially of the material comprised in the layer (i.e. there are substantially no spaces within the layer). A compact layer may have low porosity (e.g. less than 10% porosity and preferably less than 1%). A compact layer may be essentially homogeneous. A compact layer may be crystalline, or may comprise microcrystalline, nanocrystalline or amorphous material. A compact layer may be an oxide, or a hydrated oxide.

The term “compact layer” may also refer to any dense layer of a semiconductor material. A compact layer may be a dense nano- or microcrystalline layer of the semiconductor material. A compact layer will often have low porosity. In particular, a compact layer will often have low mesoporosity and low macroporosity. Thus, a compact layer may be a layer which has substantially no macropores. A compact layer may be a layer which has substantially no macropores and substantially no mesopores, as defined below. The thickness of the layer may vary. Compact layers are typically layers of a semiconductor material that act as selective contacts at an electrode.

When the process is a process for producing a mesoporous layer of a semiconductor material (optionally comprising mesoporous particles), the substrate typically comprises a compact layer of a semiconductor material. The substrate typically also comprises an electrode material. A mesoporous layer produced by the process of the invention will typically be disposed on (i.e. in contact with) a compact layer of a semiconductor material. Thus, when the layer of a semiconductor material is a mesoporous layer, the substrate often comprises a layer of an electrode material as defined anywhere herein and a compact layer of a semiconductor material as defined anywhere herein, and the layer of a semiconductor material is disposed on the compact layer of a semiconductor material.

When the process is a process for producing a compact layer of a semiconductor material (optionally comprising nanoparticles), the substrate typically comprises an electrode material. A compact layer produced by the process of the invention will typically be disposed on (i.e. in contact with) a layer of the electrode material. Thus, when the layer of a semiconductor material is a compact layer, the substrate often comprises a layer of an electrode material as defined anywhere herein, and the compact layer of a semiconductor material is disposed on the layer of the electrode material.

Typically, the solvent is an organic solvent or, if first and second solvents are present, the first solvent is an organic solvent, the second solvent is an organic solvent, or both first and second solvents are organic solvents. The term “organic solvent”, as used herein, refers to a solvent the molecules of which comprise at least one carbon atom and typically at least one hydrogen atom. The term is well known. The organic solvent may be an alcohol, a thiol, an ether, a ketone, an aldehyde, an alkane, a cycloalkane, an aromatic hydrocarbon, a heterocyclic compound, an aromatic heterocyclic compound, a halogenated hydrocarbon, or an amine. The term “alcohol”, as used herein, refers to a compound which comprises one or more hydroxyl groups. Examples of such compounds include C₁-C₈-alcohols. Di-, tri- and poly-ols are also included (e.g. ethylene glycol or propylene glycol). The term “thiol”, as used herein, refers to a compound which comprises one or more thiol (—SH) groups. Examples of such compounds include C₁-C₈-alkylthiols. The term “ether”, as used herein, refers to a compound which comprises one more ether groups (i.e. those of the form R₃C—O—CR₃). Examples of such compounds include di-C₁-C₈-alkylethers and saturated heterocycles containing an oxygen atom between two carbon atoms. The term “ketone”, as used herein, refers to a compounds which comprise one or more oxo groups (>C═O) at least one of which is not on a terminal carbon. Examples of such compounds include acetone, butanone and acetoacetone. The term “aldehyde”, as used herein, refers to compounds comprising a formyl (—CHO) group. Examples of such compounds include formaldehyde and ethanal. The term “alkane”, as used herein, refers to a linear or branched saturated hydrocarbon. Typically the alkane is a C₅-C₁₀-alkane. Examples of such alkane organic solvents are pentane, hexane and heptane. The term “cycloalkane”, as used herein, refers to a cyclic alkane molecule, typically cyclopentane or cyclohexane. The term “aromatic hydrocarbon”, as used herein, refers to a compound comprising an aromatic hydrocarbon ring, typically a benzene ring. Examples of such compounds include benzene, toluene, and xylene. The term “heterocyclic compound”, as used herein, refers to a cyclic compound comprising one or more heteroatom (i.e. an atom which is not carbon). Examples of heterocyclic compounds include tetrahydrofuran, pyrollidine and aromatic heterocyclic compounds. The term “aromatic heterocyclic compound”, as used herein, refers to aromatic compounds comprising at least one heteroatom in the aromatic ring. Examples of aromatic heterocyclic compounds include pyrrole and pyridine. The term “halogenated hydrocarbon”, as used herein, refers to a hydrocarbon compound (i.e. a compound consisting of only carbon and hydrogen) in which one or more hydrogen atoms have been replaced with halogen atoms. Typically the halogenated hydrocarbon will have between 1 and 8 carbons. Examples of such compounds include chloroform. The term “amine”, as used herein, refers to an organic compound which comprises at least one saturated nitrogen atom. Examples of such compounds include tri-C₁-C₈-alkylamines.

The solvent or solvents are often anhydrous solvents. Anhydrous solvents are those which comprise less than or equal to 1 wt % of water (relative to the total mass of the solvent). In particular, when the process is a process for producing a compact layer of a semiconductor material, the solvent or solvents are typically anhydrous alcohols. There may be a single solvent, and that solvent may be an anhydrous alcohol.

Preferably, the solvent or solvents are selected from methanol, ethanol, propanol, isopropanol, butanol, secbutanol or tertbutanol. The solvent or solvents are preferably ethanol.

In one embodiment, the solvent is a single solvent and is anhydrous alcohol. The solvent may be a single solvent which is anhydrous ethanol.

In one embodiment, the solvent is water or, if first and second solvents are present, the first solvent is water, the second solvent is water or both the first and the second solvents are water.

The terms “removing the solvent” or “removing the solvents”, as used herein, refer to removal of all or a part of the solvent or solvents from a composition. Preferably, all solvent present is removed, although traces (e.g. less than 1 wt %) of solvent may remain without necessarily affecting the performance of the resulting semiconductor layer. If part of the solvent is removed, it is preferably a substantial part of the solvent (e.g. greater than 90%) which is removed. If more than one solvent is present, removal of the solvent may refer to removal to all of, or a substantial part of, both solvents.

In the process of the present invention, the inventors have found that a binder, wherein the binder is a molecular compound comprising at least one metal atom or metalloid atom, can be used to form a layer of particles of a semiconductor material with good electron transport properties whilst obviating the need for high temperature (i.e. greater than 300° C.) sintering.

The term “binder”, as used herein, refers to an additive that improves binding between particles in a film when the film has dried.

Typically, the binder further comprises one or more atoms selected from O, S, Se and Te.

A wide range of binder compounds will successfully bind the plurality of particles of a semiconductor material together to form a layer with effective electron transport properties. In some cases, the binder will form bridges between separate adjacent particles of a semiconductor material upon removal of the solvent. In other cases the binder will form layers over the surface of the particles of a semiconductor material. It is preferable that on removal of the solvent the binder molecule will, at least in part, form a solid with semiconducting properties. Binder-type compounds known in the art include organic polymeric compounds such as cellulose (Ito et al., “Fabrication of Screen-Printing Pastes from TiO₂ Powders for Dye-Sensitized Solar Cells”, Progress in Photovoltaics 15, 603 (2007)) The use of binders such as cellulose in a process for producing layers of a semiconductor material leads to layers where the individual particles are only physically bound-there is no potential for formation of bridging bonds or shells of semiconducting material which lead to efficient electron transport properties.

The binder used in the current invention is a molecular compound comprising at least one metal atom or metalloid atom. Typically, the binder is a molecular compound comprising at least one metal atom or metalloid atom and one or more atoms selected from O, S, Se and Te. For instance, the binder may comprise at least one metal or metalloid atom and one or more groups comprising one or more atoms selected from O, S, Se and Te. Typically, the one or more groups are bonded to a said metal atom or metalloid atom through at least one of the oxygen, sulphur, selenium or tellurium atoms. The binder may be a molecular compound comprising at least one metal atom or metalloid atom and one or more organic groups comprising one or more oxygen, sulphur, selenium or tellurium atoms. For instance, the molecular compound may comprise one or more groups of formula XR, wherein each X is the same or different and is an atom selected from O, S, Se and Te, and each R is the same or different and is an unsubstituted or substituted C₁-C₈ hydrocarbyl group. If the molecular compound comprises two or more groups of formula XR, two or more R groups may be bonded to each other. Usually, the one or more groups of XR are bonded to a said metal atom or metalloid atom through X. Examples of such organic groups comprising one or more oxygen, sulphur, selenium or tellurium atoms include groups derived from alcohols (e.g. alkoxide), thiols, selenols, diols, polyols, amino acids, carboxylic acids and dicarboxylic acids (e.g. oxalate).

In one embodiment, the binder is a molecular compound comprising at least one metal or metalloid atom provided that the binder is not titanium tetrachloride (TiCl₄).

In one embodiment, the binder is a molecular compound with the formula [MₐY_{b}(XR)_{c}Z_{d}] wherein

each M is the same or different and is a metal atom or a metalloid atom;

each X is the same or different and is an atom selected from O, S, Se, and Te;

each Y is the same or different and is an atom selected from O, S, Se, and Te;

each Z is the same or different and is a monodentate group;

each R is the same or different and is an unsubstituted or substituted C₁-C₈ hydrocarbyl group, wherein two or more R groups may be bonded to each other;

a is an integer from 1 to 4;

b is 0 or an integer from 1 to 7;

c is an integer from 1 to 16;

d is 0 or an integer from 1 to 15; and

2b+c+d is less than or equal to the total valence of the one or more M atoms.

The term “monodentate group”, as used herein, refers to groups which bind to one or more of the central metal or metalloid atoms through only a single atom in the group. Examples of monodentate groups include C₁-C₈-hydrocarbyl groups, C₁-C₈-alkyl groups, amino, mono-C₁-C₈-alkylamine groups, di-C₁-C₈-alkylamine groups, tri-C₁-C₈-alkylamine groups, hydro, hydroxide, phosphine, tri-C₁-C₈-alkylphosphine and halogen groups. In particular, the monodentate group may be a halogen atom, i.e. F, Cl, Br or I.

Typically, the binder is a molecular compound with the formula [MₐY_{b}(XR)_{c}] wherein

each M is the same or different and is a metal atom or a metalloid atom;

each X is the same or different and is an atom selected from O, S, Se, and Te;

each Y is the same or different and is an atom selected from O, S, Se, and Te;

each R is the same or different and is an unsubstituted or substituted C₁-C₈ hydrocarbyl group, wherein two or more R groups may be bonded to each other;

a is an integer from 1 to 4;

b is 0 or an integer from 1 to 7;

c is an integer from 1 to 16; and

2b+c is less than or equal to the total valence of the one or more M atoms.

Typically, a is an integer from 1 to 4. For example, a is from 1 to 3, or 1, 2, 3 or 4. Preferably a is 1. When a is greater than 1, the compound is polynuclear and some of the ligands may bridge between two or more metal or metalloid atoms, or there may be M-M bonds between metal or metalloid atoms. An example of a polynuclear molecular compound is W₂O₂(OCy)₈ (where Cy is cyclohexyl). Typically, b is 0 or an integer from 1 to 7. For example, b is from 0 to 6, from 0 to 5, from 0 to 4, from 0 to 3, from 0 to 2, from 1 to 6, from 1 to 5, from 1 to 4, from 1 to 3 or 0, 1, 2, 3, 4, 5 or 6. Typically, c is an integer from 1 to 16. For example, c is from 1 to 10, from 1 to 8 or from x to y where x and y are any integers selected from 1 to 16 and y is greater than x. Typically d is 0 or an integer from 1 to 15. For example, d is from 0 to 12, from 0 to 10, from 1 to 15, from 1 to 13 or from x to y where x and y are any integers selected from 0 to 15 and y is greater than x.

Examples of compounds falling within the formula [MₐY_{b}(XR)_{c}] described above include: alkoxides [M(OR)_{c}] (e.g. Ti(OCH(CH₃)₂)₄, Nb(OCH₂CH₃)₅ and Si(OCH₂CH₃)₄); oxide alkoxides [MO_{b}(OR)_{c}]; polynuclear oxide alkoxides [MₐO_{b}(OR)_{c}] (e.g. Re₄O₆(OCH₃)₁₂ and W₂O₂(OCy)₈ where Cy is cyclohexyl); diolates [M(O-alkylene-O)_{c}]; thiolates [M(SR)_{c}]; sulphide alkoxides [MS_{b}(OR)_{c}]; 1,3-diketonates [M(R(CO)CR(CO)R)_{c}] (e.g. Cr(acac)₃ and Cu(acac)₂); alkoxide 1,3-diketonates [M(OR)_{c}(R(CO)CR(CO)R)_{c′}] (e.g. Ti(OCH(CH₃)₂)₂(acac)₂); and polynuclear sulphide 1,3-diketonates [MₐS_{b}(R(CO)CR(CO)R)_{c}] (e.g. Nb₂(S)₂(acac)₂).

Preferably, the binder is a molecular compound with the formula [MOₑ(OR)_{f}] wherein

M is a metal atom or a metalloid atom;

each R is the same or different and is an unsubstituted or substituted C₁-C₈ hydrocarbyl group, wherein two or more R groups may be bonded to each other;

e is 0 or an integer from 1 to 3;

f is an integer from 1 to 8; and

2e+f is equal to the valence of M.

Typically e is 0 or an integer from 1 to 3. For example, e is from 0 to 2, from 1 to 3, or 0, 2, or 3. Typically, f is an integer from 1 to 8. For example, f is from 1 to 7, from 1 to 6, from 1 to 5, from 2 to 7, from 2 to 6, from 2 to 5, from 1 to 4, or 1, 2, 3, 4, 5, 6, 7 or 8

In one embodiment the binder is a molecular compound of formula (1)

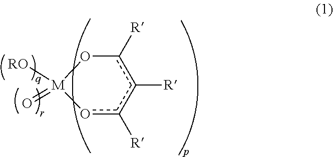

wherein

M is a metal atom or a metalloid atom;

each R is the same or different and is an unsubstituted or substituted C₁-C₈ hydrocarbyl group, wherein two or more R groups may be bonded to each other;

each R′ is the same or different and is H or an unsubstituted or substituted C₁-C₃ group, wherein two or more R′ groups may be bonded to each other;

p is an integer from 1 to 4;

q is 0 or an integer from 1 to 6;

r is 0 or an integer from 1 to 3; and

2p+q+2r is equal to the valence of M.

In another embodiment, the binder is a molecular compound of formula (2)

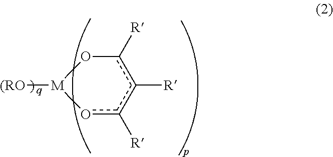

wherein

M is a metal atom or a metalloid atom;

each R is the same or different and is an unsubstituted or substituted C₁-C₈ hydrocarbyl group, wherein two or more R groups may be bonded to each other;

each R′ is the same or different and is H or an unsubstituted or substituted C₁-C₃ group, wherein two or more R′ groups may be bonded to each other;

p is an integer from 1 to 4;

q is 0 or an integer from 1 to 6; and

2p+q is equal to the valence of M.

Typically, p is an integer from 1 to 4. For example, p is from 1 to 3, from 2 to 4, or 1, 2, or 4. Typically, q is 0 or an integer from 1 to 6. For example, q is from 0 to 5, from 1 to 5, from 0 to 4, from 1 to 4, from 2 to 4, or 1, 2, 3, 4, 5 or 6. Typically, r is 0 or an integer from 1 to 3 For example, r is from 1 to 3, from 0 to 2, or 0, 1, 2, or 3.

Generally, M is selected from the elements of groups 3 to 12 of the periodic table of the elements, Al, Ga, In, Tl, Sn, Pb, Bi, B, Si, Ge, As, Sb and Te. Preferably, M is selected from Zr, V, Nb, Ti and Si. M may be selected from V, Nb, Ti and Si. Most preferably, M is Ti.

Occasionally, the binder is a molecular compound comprising at least one metal or metalloid atom and one or more halogen atoms. The halogen atoms are F, Cl, Br and I. For example, the binder compound may be a cadmium halide, such as cadmium fluoride, cadmium chloride, cadmium bromide or cadmium iodide. The binder compound may be cadmium chloride (CdCl₂).

Thus, for instance, the binder may be selected from: (i) a molecular compound comprising at least one metal atom or metalloid atom and one or more atoms selected from O, S, Se and Te; and (ii) a molecular compound comprising at least one metal or metalloid atom and one or more halogen atoms. The molecular compound (i), which comprises at least one metal atom or metalloid atom and one or more atoms selected from O, S, Se and Te, may be as further defined herein. The molecular compound (ii), which comprises at least one metal or metalloid atom and one or more halogen atoms, may also be as further defined herein. However, typically, the metal or metalloid atom in the molecular compound (ii), which comprises at least one metal or metalloid atom and one or more halogen atoms, is other than titanium.

The terms “metal atom” and “metalloid atom”, as used herein, are as defined above.

The term “hydrocarbyl group”, as used herein, means any monovalent group derived from the removal of a single hydrogen atom from a hydrocarbon compound, wherein a hydrocarbon compound is a compound consisting solely of carbon and hydrogen atoms. The term “C₁-C₈ hydrocarbyl group” means a hydrocarbyl group containing from 1 to 8 carbon atoms. Examples of C₁-C₈ hydrocarbyl groups include C₁-C₈ alkyl groups, C₂-C₈ alkenyl groups, C₂-C₈ alkynyl groups, C₃-C₈ cycloalkyl groups, C₃-C₈ cycloalkenyl groups, C₆-C₈ aryl groups and C₆-C₈ arylalkyl groups. Examples of C₁-C₈ alkyl groups include methyl, ethyl, propyl, isopropyl, butyl, secbutyl, tertbutyl, pentyl, 1-methylbutyl, 2-methylbutyl, 3-methylbutyl, 1,1-dimethylpropyl, 1,2-dimethylpropyl, 1-ethylpropyl, neopentyl, hexyl, heptyl and octyl. Examples of C₂-C₈ alkenyl groups include vinyl, propenyl, butenyl, pentenyl, hexenyl, heptenyl and octenyl wherein the double bond may take any position in the carbon chain. Examples of C₂-C₈ alkynyl groups include ethenyl, propynyl, butynyl, pentynyl, hexynyl, heptynyl and octynyl wherein the triple bond may take any position in the carbon chain. Each of these groups may be straight-chain or branched. Examples of C₃-C₈ groups include cyclopropyl, cyclobutyl, cyclopentyl, cyclohexyl, cycloheptyl and cyclooctyl wherein hydrogen atoms in said cycloalkyl groups may be substituted with further alkyl groups (provided the total number of carbons in the group is less than 8). Examples of C₆-C₈ aryl groups include phenyl, ortho-, meta- or paramethylphenyl, dimethylphenyl and ethylphenyl. Examples of C₆-C₈ arylalkyl groups include benzyl, 1-phenylethyl and 2-phenylethyl. In all cases, any other structural isomers of the given groups are also included. If the term “alkyl” is used without a prefix defining the number of carbons, then “alkyl” typically means C₁-C₈-alkyl as defined above. If the prefix “alk-” is used (e.g. as in alkoxide) without a further prefix defining the number of carbon atoms, then “alk-” typically means that 1 to 8 or 2 to 8 carbon atoms are present (depending on the form of the group that “alk-” prefixes). References to C₁-C₈ are to be understood to include references to C₁-C₇, C₂-C₇, C₁-C₆, C₂-C₆, C₁-C₅, C₂-C₅, C₁-C₄, C₂-C₄, and C₁-C₃.

The term “substituted”, as used herein, refers to a group wherein a hydrogen atom has been replaced with a substituent. When a group is substituted it typically bears one or more substituents (for instance 1, 2 or 3 substituents) selected from: C₁-C₈ alkyl, C₂-C₈ alkenyl, C₂-C₈ alkynyl, aryl (as defined herein), heteroaryl, cyano, amino, C₁-C₈ alkylamino, di(C₁-C₈)alkylamino, arylamino, diarylamino, arylalkylamino, amido, acylamido, hydroxy, oxo, halo, carboxy, ester, acyl, acyloxy, C₁-C₈ alkoxy, aryloxy, haloalkyl, sulfonic acid, sulfhydryl (i.e. thiol, —SH), C₁-C₈ alkylthio, arylthio, sulfonyl, phosphoric acid, phosphate ester, phosphonic acid and phosphonate ester. The term alkaryl, as used herein, pertains to a C₁-C₈ alkyl group in which at least one hydrogen atom has been replaced with an aryl group. Examples of such groups include, but are not limited to, phenyl, benzyl (phenylmethyl, PhCH₂—), benzhydryl (Ph₂CH—), trityl (triphenylmethyl, Ph₃C—), and phenethyl (phenylethyl, Ph-CH₂CH₂—). C₁-C₈ alkyl, C₂-C₈ alkenyl, C₂-C₈ alkynyl are as defined above.

An aryl group is an aromatic group which typically contains from 6 to 10 carbon atoms in the ring portion. Examples include phenyl and naphthyl. A heteroaryl group is a heteroaromatic group which typically contains from 6 to 10 atoms in the ring portion including one or more heteroatoms. It is generally a 5- or 6-membered ring, containing at least one heteroatom selected from O, S, N, P, Se and Si. It may contain, for example, 1, 2 or 3 heteroatoms. Examples of heteroaryl groups include pyridyl, pyrazinyl, pyrimidinyl, pyridazinyl, furanyl, thienyl (i.e. thiophenyl), pyrazolidinyl, pyrrolyl, oxazolyl, oxadiazolyl, isoxazolyl, thiadiazolyl, thiazolyl, isothiazolyl, imidazolyl, pyrazolyl, quinolyl and isoquinolyl.

The phrase “where two or more R groups may be bonded to each other”, as used herein, refers to compounds in which a bond is formed between any one carbon atom in one R group and any one carbon atom in a second R group, and any one carbon atom in either of these R groups may then be bonded to any one carbon atom in a third or further R group. There may be more than one bond between any two R groups. Examples of groups that may be formed by bonding between R groups include butan-2,3-diolate, cyclohexan-1,2-diolate and 2,4-dimethylpentan-1,5-diolate. The same principle applies for the phrase “where two or more R′ groups may be bonded to each other”.

The term “valence”, as used herein, refers to the number of valence bonds that an atom (or ion) has formed, or can form, with one or more other atoms or groups. A valence bond is a bond in which atomic orbitals on the two constituent atoms bonded together lead to the formation of a molecular orbital, at least in part. Valence bonds are those with a significant amount of covalent character wherein electrons are shared between the two atoms (as opposed to bonds of predominantly ionic character). The valence of an atom (or ion) will depend on the identity of the atom itself, the oxidation state of the atom and the nature of the atoms or groups to which it is bonded. Typically, the valence of a metal and metalloid atom (or ion) will range from 1 to 8. The valence of a metal atom (or ion) from group 1 of the periodic table of the elements is typically 1. The valence of a metal atom (or ion) from group 2 of the periodic table of the elements is typically 2. The valence of a metal atom (or ion) taken from groups 3 to 12 of the periodic table of the periodic table of the elements may take a range of values, but is typically 2, 4 or 6. The valence of a metal or metalloid atom (or ion) taken from group 13 of the periodic table of the elements is typically 3. The valence of a metal or metalloid atom (or ion) taken from group 14 of the periodic table of the elements is typically 4 or occasionally 6 in the case of Sn and Pb. The valence of a metal or metalloid atom (or ion) taken from group 15 of the periodic table of the elements is typically 3 or 5. The valence of a metal or metalloid atom (or ion) taken from group 16 of the periodic table of the elements is typically 2, 4, or 6. In the case of polynuclear compounds, the term “total valence of the one or more M atoms”, as used herein, refers to the sum of the valence on each of the M atoms in the polynuclear compound. Some of the valence electrons in each M in the polynuclear molecular compound will be used for forming M-M bonds.

In formulae (1) and (2) “---” means that these bonds have a character intermediate between single and double bonds. In different resonance structures of the group the bonds will either be single or double bonds.

The phrase “groups 3 to 12 of the periodic table of the elements”, as used herein, means the elements that fall within these groups of the periodic table of the elements. Groups 3, 4, 5, 7, 8, 9, 10, 11 and 12 are included and these groups contain the elements Sc, Y, Lu, Ti, Zr, Hf, V, Nb, Ta, Cr, Mo, W, Mn, Re, Fe, Ru, Os, Co, Rh, Ir, Ni, Pd, Pt, Co, Ag, Au, Zn, Cd and Hg.

In one embodiment, the binder is selected from: titanium di(C₁-C₈-alkoxide) bis(acetylacetonate); niobium ethoxide; a metal compound comprising an acetylacetonate group, wherein the metal is selected from titanium, zirconium, vanadium, niobium, chromium, molybdenum, tungsten, manganese, rhenium, iron, ruthenium, osmium, cobalt, rhodium, iridium, nickel, palladium, platinum, copper, zinc and aluminium; tetra(C₁-C₈-hydrocarbyl) orthosilicates; tri(C₁-C₈-hydrocarbyl) borates; and cadmium chloride. The C₁-C₈-alkoxide and C₁-C₈-hydrocarbyl groups may be the same or different.

In a preferred embodiment, the binder is selected from titanium di-isopropoxide bis(acetylacetonate), vanadium acetyl acetonate, niobium ethoxide and tetraethyl orthosilicate.

Optionally, the binder compound may be a molecular compound comprising a metal or metalloid atom and at least one 1,3-diketonate group.

The term “C₁-C₈-alkoxide”, as used herein, refers to an alkoxide group comprising 1 to 8 carbon atoms, i.e. a group of the formula RO⁻ wherein R is a C₁-C₈-alkyl group. Examples of C₁-C₈-alkoxide groups include methoxide, ethoxide, propoxide, isopropoxide, butoxide, secbutoxide, and tertbutoxide, and any C₅-C₈-alkoxide groups. Any C₁-C₈-alkoxide group may be optionally substituted or unsubstituted, wherein “substituted” is as defined above.

The term “acetylacetonate”, as used herein, means the (anionic) group obtained by the removal of a proton from the carbon at the 3-position in pentane-2,4-dione (also known as acetylacetone). Acetylacetonate typically acts as a bidentate moiety and is bound to a central atom through both oxygen atoms. Acetylacetone is an example of a 1,3-diketone. Acetylacetonate is an example of a 1,3-diketonate. Alternatively, acetylacetonate can act as a monovalent moiety bound solely through the central carbon atom. Acetylacetonate can tautomerise between these two modes of bonding. The shorthand “acac” or “AcAc” is used to indicate the presence of an acetylacetonate group in a compound and represents the anion [OC(CH₃)CHC(CH₃)O]⁻. The term “metal acetylacetonate”, as used herein, means a compound comprising at least one central metal atom and at least one acetylacetonate group. A metal acetylacetonate compound may also comprise other groups bound to the at least one central metal atom, including, for example: oxide, sulfide, selenide and telluride; halide, including fluoride, chloride, bromide and iodide; carbonyl (CO); C₁-C₈-alkyl and C₁-C₈-alkoxide; and di-C₁-C₈-alkylamine and C₁-C₈-alkylamide. The following compounds are exemplary, amongst others, of metal acetylacetonates: titanium di-isopropoxide bis(acetylacetonate) [Ti(OCH(CH₃)₂)₂(acac)₂]; titanium oxide bis(acetylacetonate) [TiO(acac)₂]; zirconium acetylacetonate [Zi(acac)₄]; vanadyl acetylacetonate [VO(acac)₂]; niobium (V) dichloro di-ethoxide acetylacetonate [NbCl₂(OCH₂CH₃)₂(acac)]; chromium (III) acetylacetonate [Cr(acac)₃]; molybdenum (HI) acetylacetonate [Mo(acac)₃]; molybdenum (VI) di-oxo bis(acetylacetonate) [Mo(O)₂(acac)₂]; manganese (III) acetylacetonate [Mn(acac)₃]; tungsten (IV) tricarbonyl bis(acetylacetonate) [W(CO)₃(acac)₂]; iron (II) acetylacetonate [Fe(acac)₂]; iron (III) cacetylacetonate [Fe(acac)₃]; ruthenium (III) acetylacetonate [Ru(acac)₃]; cobalt acetylacetonate [Co(acac)₃]; nickel (II) acetylacetonate [Ni(acac)₂]; copper acetylacetonate [Cu(acach]; zinc acetylacetonate [Zn(acac)₂]; and aluminium acetylacetonate [Al(acac)₃], In the case of compounds for which there are enantiomers, diastereomers, tautomers, salts or hydrates, any of these may be used. Reference to metal acetylacetonates also includes references to any dimeric, trimeric or oligimeric forms in which they might exist, such as the tetrameric form of anhydrous cobalt acetylacetonate, [Co(acac)₂]₄.

Generally, in the case of any binder or molecular compound used in the invention, any enantiomers, diastereomers, tautomers, salts or hydrates, dimers or trimers may be used.

The term “tetra-C₁-C₈-hydrocarbyl orthosilicates”, as used herein, means any compound with the formula Si(OR)₄ wherein R is a C₁-C₈-hydrocarbyl as defined above. The term “tri-C₁-C₈-hydrocarbyl borates”, as used herein, means any compound with the formula B(OR)₃ wherein R is a C₁-C₈-hydrocarbyl as defined above. In both cases, the C₁-C₈-hydrocarbyl group may be substituted or unsubstituted, where “substituted” is as defined above.

As discussed above, the particles of a semiconductor material may be of any shape, form or size. Preferably, however, in order to benefit from the electronic properties of the semiconductor material, the particles are preferably not amorphous.

In one embodiment, the particles of a semiconductor material comprise single crystals or poly crystals of the semiconductor material. In a preferred embodiment, the particles comprise single crystals of the semiconductor material. The particles of a semiconductor material may consist of single crystals or polycrystals of the semiconductor material. Usually the particles are single crystals of the semiconductor material. Thus, in another embodiment, the particles consist of single crystals of the semiconductor material.

Often, it is desirable to produce a compact layer of a semiconductor material. Thus, in one embodiment, the layer of a semiconductor material is a compact layer of the semiconductor material.

To obtain a compact layer of the semiconductor material, it is preferable to use small particles of the semiconductor material which will produce low porosity films. Compact layers may be used as blocking layers in semiconductor devices. Compact layers also function as electron selective contacts at the anode, or hole selective contacts at the cathode. It is desirable that a compact layer is dense and has a low open porosity.

Thus, in one embodiment, the layer of a semiconductor material is a layer without open porosity. Compact layers do not typically have macropores or mesopores (which are as defined below). Thus, often, when the layer of a semiconductor material is a compact layer of a semiconductor material, the layer of a semiconductor material has substantially no macropores. The term “substantially no macropores”, as used herein, refers to a solid with a porosity, wherein less than or equal to 10% of said porosity is found in macropores. Less than or equal to 5% of said porosity may be found in macropores. Typically, less than or equal to 1% of said porosity is found in macropores. Often, when the layer of a semiconductor material is a compact layer of a semiconductor material, the layer of a semiconductor material has substantially no macropores and substantially no mesopores. The term “substantially no macropores and substantially no mesopores”, as used herein, refers to a solid with a porosity, wherein less than or equal to 10% of said porosity is found in macropores and less than or equal to 10% of said porosity is found in mesopores. Less than or equal to 5% of said porosity may be found in macropores and less than or equal to 5% of said porosity may be found in mesopores. Typically, less than or equal to 1% of said porosity is found in macropores and less than or equal to 1% of said porosity is found in mesopores. As defined below, mesopores have widths (i.e. pore sizes) of from 2 nm to 50 nm and macropores have widths (i.e. pore sizes) of greater than 50 nm. A compact layer may comprise micropores. A compact layer may be microporous. Thus, the average pore size of the compact layer may be less than or equal to 2 nm. Sometimes, the layer of a semiconductor material is substantially non-porous. A layer which is substantially non-porous typically has a porosity of less than or equal to 5%, for instance less than or equal to 1%.

As used herein, the term “porous” refers to a material within which pores are arranged. Thus, for instance, in a porous scaffold material the pores are volumes within the scaffold where there is no scaffold material. The individual pores may be the same size or different sizes. The size of the pores is defined as the “pore size”. The limiting size of a pore, for most phenomena in which porous solids are involved, is that of its smallest dimension which, in the absence of any further precision, is referred to as the width of the pore (i.e. the width of a slit-shaped pore, the diameter of a cylindrical or spherical pore, etc.). To avoid a misleading change in scale when comparing cylindrical and slit-shaped pores, one should use the diameter of a cylindrical pore (rather than its radius) as its “pore-width” (J. Rouquerol et al., “Recommendations for the Characterization of Porous Solids”, Pure & Appl. Chem., Vol. 66, No. 8, pp. 1739-1758, 1994). The following distinctions and definitions were adopted in previous IUPAC documents (K. S. W. Sing, et al, Pure and Appl. Chem, vol. 57, n04, pp 603-919, 1985; and IUPAC “Manual on Catalyst Characterization”, J. Haber, Pure and Appl. Chem., vol. 63, pp. 1227-1246, 1991): Micropores have widths (i.e. pore sizes) smaller than 2 Mesopores have widths (i.e. pore sizes) of from 2 nm to 50 nm; and Macropores have widths (i.e. pore sizes) of greater than 50 nm.

Pores in a material may include “closed” pores as well as open pores. A closed pore is a pore in a material which is a non-connected cavity, i.e. a pore which is isolated within the material and not connected to any other pore and which cannot therefore be accessed by a fluid (e.g. a liquid, such as a solution) to which the material is exposed. An “open pore” on the other hand, would be accessible by such a fluid. The concepts of open and closed porosity are discussed in detail in J. Rouquerol et al., “Recommendations for the Characterization of Porous Solids”, Pure & Appl. Chem., Vol. 66, No. 8, pp. 1739-1758, 1994.

Open porosity, therefore, refers to the fraction of the total volume of the porous material in which fluid flow could effectively take place. It therefore excludes closed pores. The term “open porosity” is interchangeable with the terms “connected porosity” and “effective porosity”, and in the art is commonly reduced simply to “porosity”.

The term “without open porosity”, as used herein, therefore refers to a material with no effective porosity. Microporous materials are often without open porosity. The term “non-porous” as used herein, refers to a material without any porosity, i.e. without open porosity and also without closed porosity.

The layer of a semiconductor material may be suitable for use as a selective contact for electron collection at an anode. The layer of a semiconductor material may be suitable for preventing recombination by electron leakage from an anode. The layer of a semiconductor material may be suitable for use as a selective contact for electron collection at an anode and/or the layer of a semiconductor material may be suitable for preventing recombination by electron leakage from an anode. Selective contacts allow the efficiency of the device to be improved by preventing loss of efficiency to due to electron/hole recombination.

The substrate typically comprises a first electrode material. As discussed above, when the layer is a compact layer, the compact layer of a semiconductor material is typically disposed on a layer of a first electrode material. Thus, the substrate often comprises a layer of a first electrode material. The substrate often comprises a layer of a first electrode material, and the process comprises disposing the compact layer of a semiconductor material on the layer of the first electrode material.

The first electrode material may comprise an electrode material as described anywhere herein, for instance a transparent conducting oxide or a metal. The first electrode material may comprise a transparent conducting oxide. Often, the first electrode material comprises a transparent conducting oxide, preferably wherein the transparent conducting oxide is selected from indium tin oxide (ITO), fluorine doped tin oxide (FTO) and aluminium doped zinc oxide (AZO). The first electrode material may be selected from ITO, FTO and AZO. Thus, the substrate may comprise a layer of ITO, FTO and AZO.

The particles of a semiconductor material are often nanoparticles of the semiconductor material. Typically, the particles of a semiconductor material are nanoparticles of the semiconductor material when the layer of a semiconductor material is a compact layer of a semiconductor material.

As used herein, the term “nanoparticle” means a microscopic particle whose size is measured in nanometres (nm). Typically, a nanoparticle has a particle size of less than or equal to 1000 nm, less than or equal to 500 nm, from 0.5 nm to 1000 nm, or for instance from 0.5 nm to 800 nm or from 0.5 nm to 600 nm. A nanoparticle may have a size from 2 nm to 1000 nm, or for instance from 2 nm to 500 nm or from 2 nm to 100 nm. Typically, a nanoparticle has a particle size of less than or equal to 400 nm, or, for instance, less than or equal to 100 nm. Often, it is preferable that the nanoparticles of the semiconductor material are of a small size to allow a dense compact layer to be formed. Therefore, a nanoparticle may have a size of less than or equal to 50 nm, less than or equal to 20 nm, less than or equal to 10 nm or, in particular, less than or equal to 5 nm. A nanoparticle may be spherical or non-spherical. Non-spherical nanoparticles may for instance be plate-shaped, needle-shaped or tubular. Typically, however, the majority of the nanoparticles may be substantially spherical. The term “particle size” as used herein means the diameter of the particle if the particle is spherical or, if the particle is non-spherical, the volume-based particle size. The volume-based particle size is the diameter of the sphere that has the same volume as the non-spherical particle in question.

For a compact layer to have good transport properties, it is often desirable that the compact layer comprises crystalline material. Thus, the nanoparticles of the semiconductor material are often crystalline. The nanoparticles may be single crystals or polycrystals. The nanoparticles of the semiconductor material may be single crystals of the semiconductor material.

As explained above, it is preferable that a compact layer is produced using small nanoparticles of the semiconductor material in order to produce a dense layer. Thus, the nanoparticles of a semiconductor material may have an average particle size of less than or equal to 20 nm, less than or equal to 10 nm, or less than or equal to 5 nm. The nanoparticles of a semiconductor material often have an average particle size of less than or equal to 10 nm

In a process for producing a compact layer, often the solvent is an alcohol or, if first and second solvents are present, the first solvent is an alcohol, the second solvent is an alcohol, or both the first and second solvents are alcohols. Typically, a process for producing a compact layer comprises: disposing on the substrate a composition comprising the solvent, the binder and the plurality of particles of a semiconductor material; and removing the solvent. Thus, a single solvent may be present. The solvent is often an alcohol. The solvent may be an anhydrous alcohol. The solvent or solvents may be selected from methanol, ethanol, propanol, isopropanol, butanol, sec-butanol, tert-butanol and benzyl alcohol. For instance, the solvent may be an anhydrous alcohol. The solvent may be ethanol. For instance, the solvent may be anhydrous ethanol.

The amount of the plurality of particles of the semiconductor material may be an amount as described anywhere herein. Typically, in the process for producing a compact layer of a semiconductor material, the amount of the plurality of the particles of the semiconductor is from 0.01 to 40 wt %, from 0.02 to 10 wt %, from 0.05 to 5 wt %, or from 0.1 to 4 wt %. Often, the amount of the plurality of the particles of the semiconductor material is from 0.05 to 5 wt %

As shown in the Examples, the amount of the binder may be varied to optimise the properties of the compact layer of the semiconductor material. The amount of the binder is typically from 1 to 40 mol %, from 5 to 35 mol %, from 10 to 30 mol %, or preferably from 15 to 25 mol %, relative to the amount of the semiconductor material. In some embodiments, the amount of the binder is from 5 to 35 mol % relative to the amount of the semiconductor material.

The process of the invention allows for the low temperature production of layers of a semiconductor material, including mesoporous and compact layers of the semiconductor material. Thus, the process is typically carried out at a temperature of less than or equal to 150° C. The process for producing a compact layer may be carried out at a temperature of less than or equal to 150° C.

The compact layer may be of any thickness, and may be of variable thickness across its extent. The compact layer of the semiconductor material often has a thickness of from 20 to 200 nm. For instance, the compact layer of the semiconductor material may have a thickness of from 10 to 1000 nm, from 20 to 200 nm, or from 20 to 100 nm. Often, it is preferable that the compact layer of the semiconductor material has a thickness of from 30 to 70 nm.

Often, the process further comprises producing the nanoparticles of a semiconductor material by a process comprising heating a composition comprising a precursor process solvent and a precursor metal halide compound.

In such an additional step of producing the nanoparticles of a semiconductor material by a process comprising heating a composition comprising a precursor process solvent and a precursor metal halide compound, the precursor metal halide compound typically decomposes in the solvent to produce a very fine suspension of nanoparticles of the semiconductor material. Thus, the precursor metal halide compound is typically a compound which decomposes to a semiconductor material upon heating in the precursor process solvent. Often, the precursor metal halide compound decomposes to form crystalline nanoparticles of a semiconductor material in the process precursor solvent.

The precursor process solvent typically comprises an alcohol selected from ethanol, propanol, isopropanol, butanol, sec-butanol, tert-butanol and benzyl alcohol. Often, the precursor process solvent is ethanol, propanol, isopropanol, butanol, sec-butanol, tert-butanol or benzyl alcohol. For instance, the precursor process solvent may comprise ethanol or benzyl alcohol, preferably benzyl alcohol. The precursor process solvent may be ethanol or benzyl alcohol, preferably benzyl alcohol. The alcohol is typically anhydrous. Thus, the solvent is often anhydrous ethanol or anhydrous benzyl alcohol.

The precursor metal halide compound is typically a compound of formula MX_{w}, wherein: M is a metal atom; each X is the same or different and is a halide atom; and w is an integer from 1 to 6. M may be any metal atom. M is selected from the elements of groups 3 to 12 of the periodic table of the elements, Al, Ga, In, Tl, Sn, Pb, Bi, B, Si, Ge, As, Sb and Te. Preferably, M is selected from Zr, V, Nb, Ti and Si. M may be selected from V, Nb, Ti and Si. Most preferably, M is Ti. Each X is a halide atom selected from F, Cl, Br and I. X may be Cl. Typically, w is from 1 to 4, or from 2 to 4. w is typically equal to the oxidation state of M. If the precursor metal halide compound comprises a metal atom M, the nanoparticles will comprise a semiconductor material which also comprises M.

Often, the precursor metal halide decomposes on heating in the precursor process solvent to form a metal oxide which is a semiconductor material. Thus, a precursor metal halide compound comprising titanium will form nanoparticles of a titanium oxide, in particular titanium dioxide.

Often the precursor compound is a metal chloride. The precursor metal halide compound may be titanium tetrachloride. Titanium tetrachloride may decompose in a precursor process solvent to form nanoparticles of titanium dioxide, in particular nanoparticles of anatase titanium dioxide.

Heating the composition comprises heating at a temperature of from 50° C. to 100° C., for instance from 70° C. to 90° C. The composition may be heated for from 1 to 24 hours, for instance from 5 to 15 hours. The composition is typically heated at a temperature of from 70° C. to 90° C. for a time of from 1 to 24 hours, or from 5 to 15 hours. After this time a suspension of nanoparticles of the semiconductor material will be formed. Precipitation of these particles may be caused by adding part of the suspension to another solvent, for instance diethyl ether. The resulting particles may be centrifuged, washed (optionally with acetone) and redispersed in a solvent, for instance anhydrous ethanol.

Nanoparticles of anatase titanium dioxide may be produced by a process comprising: (i) adding anhydrous TiCl₄ to anhydrous ethanol; (ii) adding the resulting solution to anhydrous benzyl alcohol; and (iii) heating the resulting composition at a temperature of from 50° C. to 100° C. for a time of from 1 to 24 hours.

Often, the particles of a semiconductor material are nanoparticles of anatase TiO₂. The particles of the semiconductor material may be nanoparticles of a semiconductor material obtainable by a process comprising heating a composition comprising a precursor process solvent and a precursor metal halide compound. The particles may be obtainable by this process, wherein the process is as further defined above.

The process of the invention may also be used to produce a mesoporous layer of a semiconductor material. Such layers may be of use in devices such as sensitized photovoltaic devices which require high surface areas Mesoporous layers may be produced by selecting larger or more porous particles than used in the production of compact layers.

To obtain an efficient semiconductor layer which has both a high surface area and good electronic properties it is preferable to use a mesoporous semiconductor material wherein the particle size extends beyond the average pore size. Accordingly, it is preferred that the particles of a semiconductor material comprise a mesoporous assembly of crystals of the semiconductor material. Such as the porous particles described by Sauvage et al. (“Dye-Sensitized Solar Cells Employing a Single Film of Mesoporous TiO₂ Beads Achieve Power Conversion Efficiencies Over 10%”, ACS Nano, 4, 4420-4425 (2010)).

To obtain the most efficient semiconductor layer which has both a high surface area and good electronic properties it is preferable to use a mesoporous crystalline semiconductor material wherein the crystal domain extends beyond the average pore size. Accordingly, it is preferred that the particles of a semiconductor material comprise mesoporous single crystals of the semiconductor material.

In one embodiment, the particles of a semiconductor material comprise mesoporous particles of the semiconductor material. Typically, the particles of a semiconductor material consist of mesoporous particles of the semiconductor material.

In one embodiment, the particles of a semiconductor material comprise mesoporous particles wherein the mesoporous particles comprise an assembly of nanocrystals. An “assembly of nanocrystals” is understood to mean any collection of two or more nanocrystals that are within a single particle and are preferably in contact with each other, although they may be aggregated in another material. Particles of a semiconductor material which comprise mesoporous particles, wherein the mesoporous particles comprise an assembly of nanocrystals, may be formed by sintering nanocrystals together at high temperature. The particles of a semiconductor material may comprise mesoporous single crystals that are obtainable by a process of growing a single crystal of the semiconductor material within a mesoporous template and subsequently removing the template material. For instance, the particles of a semiconductor material may comprise mesoporous single crystals of the semiconductor material wherein the shortest external dimension of each of the mesoporous single crystals, measured along any of the crystallographic principle axes of the crystal, is greater than or equal to 50 nm. Typically, said shortest external dimension of said single crystal is equal to or greater than 100 nm. More typically, said shortest external dimension of said single crystal is equal to or greater than 500 nm. Said shortest external dimension of said single crystal may for instance be from 50 nm to 100 μm. The shortest external dimension of said single crystal is usually from 200 nm to 10 μm. Said shortest external dimension of said single crystal may for instance be from 300 nm to 10 μm, or for instance from 500 nm to 10 μm.

Alternatively, the particles of a semiconductor material may comprise mesoporous single crystals of the semiconductor material wherein the volume of each of the mesoporous single crystals is greater than or equal to 1.25×10⁵ nm³. For instance, the volume of said single crystal may be equal to or greater than 1,000,000 nm³. More typically, the volume of said single crystal is equal to or greater than 1.25×10⁸ nm³. The volume of said single crystal may for instance be from 1.25×10⁵ nm³ to 1,000,000 μm³. In some embodiments, it is from 1.25×10⁸ nm³ to 1,000 μm³.

The term “single crystal”, as used herein, refers to a crystal in which the crystal lattice is continuous and unbroken to the edges of the crystal. A single crystal is formed by the growth of a crystal nucleus without secondary nucleation. Ideally, a single crystal is without internal boundaries or defects in atomic packing.

The term “mesoporous single crystal”, as used herein, refers to a single crystal of a material, in this case a semiconductor material, with a mesoporous structure. The semiconducting material forms a framework, within which pores are arranged. The pores within the mesoporous single crystal are the volumes within the crystal where there is no semiconductor material.

The term “mesoporous”, as used herein means that the pores in the porous structure are microscopic and have a size which is usefully measured in nanometres (nm). The mean pore size of the pores within a “mesoporous” structure may for instance be anywhere in the range of from 0.5 nm to 1,000 nm, or for instance from 1 nm to 1,000 nm. The mean pore size of the pores within a mesoporous structure may for example be from 1 nm to 500 nm, or for instance from 1 nm to 300 nm. The mean pore size of the pores within the mesoporous single crystal may for instance be from 5 nm to 200 nm. Typically, the mean pore size of the pores within said mesoporous single crystal is from 5 nm to 150 nm. Preferably the mean pore size is from 10 to 100 nm. Individual pores may be different sizes and may be any shape.

The term “pore size”, as used herein, defines the size of the pores. For spherical pores, the pore size is equal to the diameter of the pore. For pores that are not spherical, the pore size is equal to the diameter of a sphere, the volume of said sphere being equal to the volume of the non-spherical pore. This definition of pore size applies to the pores within said mesoporous single crystal and the pores within said porous template.

The porosity of the mesoporous single crystals is typically equal to or greater than 30%. The porosity of the single crystals may for instance be equal to or greater than 50%. Usually, the porosity of the mesoporous single crystals is from 50% to 70%.

The term “polycrystal”, as used herein, refers to a particle of a solid material, in this case a semiconductor material, which comprises a plurality of crystallites (i.e. individual microscopic crystals) arranged in a variety of orientations and having a variety of sizes.

In some embodiments, the aspect ratio of the mesoporous single crystals is greater than or equal 1.3. The aspect ratio may for instance be greater than or equal 1.5. In some embodiments, the aspect ratio is greater than or equal to 2. The aspect ratio may for example be greater than or equal to 10, for instance is greater than or equal to 20. The aspect ratio is in some embodiments greater than or equal to 50.

Typically, the surface area of a mesoporous material (whether a layer or a single crystal) is equal to or greater than 25 m²/g. The surface area of a mesoporous material may for instance be from 25 m²/g to 250 m²/g. In some embodiments, the surface area is from 50 m²/g to 150 m²/g, or for instance from 50 m²/g to 100 m²/g. The same applies for materials with a high surface area.

The term “template material”, as used herein, refers to any suitable material comprising pores. The template has an open structure in which pores are interconnected. This open structure enables single crystals to grow within the pores of the template material. Examples of such template materials are mesoporous inorganic materials, for instance silica or aluminosilicate. Alternatively, it may comprise a mesoporous carbon-based material. For instance, the mesoporous template material may be mesoporous black carbon, or a mesoporous polymer, for instance a block copolymer. The process of growing single crystals within a mesoporous template material is discussed in GB1203881, the entirety of which is incorporated herein by reference. The template material may be removed by any method, but examples include removal by etching, dissolving, decomposing, degrading or melting the mesoporous template material.

The “shortest external dimension” of said single crystal, as used herein, means the shortest distance from one end of the crystal to the other as measured along any of the crystallographic principal axes. Generally, this means the shortest of the length, width or breadth of the crystal as measured along any of the crystallographic principal axes. For example, cubic, tetragonal and orthorhombic crystals have three crystallographic principal axes, denoted a, b and c respectively, which correspond to the three edges of the crystal that are perpendicular to each other. In these cases, the shortest external dimension of the crystal is the shortest of the length, width and breadth of the crystal as measured along the three principal axes a, b and c. (Of course, if the crystal is an ideal cube then the external dimensions measured along the three principal axes a, b and c will be the same, and any of these three distances can therefore be taken to be the “shortest external dimension” of the crystal.)

Individual mesoporous single crystals can be imaged using electron microscopy, for instance scanning electron microscopy (SEM). These images may then be used to obtain the shortest external crystal dimension. The average external dimension of the crystal can be measured by light scattering of a liquid dispersion of the crystals. X-ray scattering can also be used to determine the crystal domain size, and hence the shortest external dimension of the crystal, via peak broadening. Thus, the shortest external crystal dimension is readily measurable using techniques which are well known to the skilled person, including by electron microscopy and by other real space imaging techniques with sufficient resolution or by X-ray scattering.

The term “volume”, in this context, refers to the geometric volume of the whole of the single crystal, including both the pores and the semiconductor. Individual mesoporous single crystals can be imaged using electron microscopy, for instance by scanning electron microscopy (SEM). These images may then be used to obtain the dimensions of the single crystal and the volume of the single crystal may be calculated.

Semiconductor materials are discussed in general above. In one embodiment, the particles of a semiconductor material comprise: an oxide or chalcogenide of a metal or metalloid element; a group IV compound; a compound comprising a group III element and a group V element; a compound comprising a group II element and a group VI element; a compound comprising a group I element and a group VII element; a compound comprising a group IV element and a group VI element; a compound comprising a group V element and a group VI element, a compound comprising a group II element and a group V element; a ternary or quaternary compound semiconductor; or an organic semiconductor.

Typically, the particles of a semiconductor material comprise an oxide or chalcogenide of a metal or metalloid element. In another embodiment, the particles of a semiconductor material comprise an oxide of titanium, niobium, tin, zinc, cadmium, copper or lead or a mixed oxide of any combination of one or more of said metals; a chalcogenide of antimony, bismuth or cadmium or a mixed chalcogenide of any combination of one or more of said metals; zinc tin oxide; copper zinc tin sulphide; copper indium gallium selenide, or copper indium gallium diselenide.

The particles of a semiconductor material may comprise an oxide of a metal or metalloid element. Preferably, the particles of a semiconductor material comprise titanium dioxide. If the particles comprise titanium dioxide, the particles may preferably comprise anatase or rutile titanium dioxide.

The terms “anatase titanium dioxide” and “rutile titanium dioxide”, as used herein, refer to the anatase and rutile mineral forms of titanium dioxide respectively. Of these two forms, the anatase form is preferred. The titanium dioxide may also be in the brookite form if desired.

Any number of combinations of binders and semiconductor materials can lead to effective semiconductor layer formation. It is not a requirement that they have a metal or metalloid atom in common present in their chemical structures, although this is often the case. Therefore, in a preferred embodiment, the semiconductor material comprises a metal or metalloid atom which is the same as one or more of the metal or metalloid atoms in the binder. For instance, possible combinations include those in which:

the binder comprises titanium di-isopropoxide bis(acetylacetonate) and the semiconductor material comprises titanium dioxide;

the binder comprises vanadium acetylacetonate and the semiconductor material comprises titanium dioxide;

the binder comprises niobium ethoxide and the semiconductor material comprises titanium dioxide;

the binder comprises titanium di-isopropoxide bis(acetylacetonate) and the semiconductor material comprises zinc oxide;

the binder comprises titanium di-isopropoxide bis(acetylacetonate) and the semiconductor material comprises tin oxide;
the binder comprises tetraethyl orthosilicate and the semiconductor material comprises tin oxide;

the binder comprises tetraethyl orthosilicate and the semiconductor material comprises silicon; or

the binder comprises cadmium chloride and the semiconductor material comprises cadmium telluride.

The process of the invention includes processes which comprise the use of particles of one or more different semiconductor materials and one or more different binders.

In one embodiment of the invention, the plurality of particles of a semiconductor material comprises a plurality of mesoporous single crystals of titanium dioxide; and the binder comprises titanium di-isopropoxide bis(acetylacetonate). Optionally, the plurality of particles of a semiconductor material comprises a plurality of mesoporous single crystals of titanium dioxide; the binder comprises titanium di-isopropoxide bis(acetylacetonate); and the solvent comprises ethanol.

For example, a process according to the invention comprises disposing on the substrate a composition comprising a solvent, a plurality of mesoporous single crystals of titanium dioxide and titanium di-isopropoxide bis(acetylacetonate), wherein the plurality of mesoporous single crystals of titanium dioxide are dispersed in the solvent and the titanium di-isopropoxide bis(acetylacetonate) is dissolved in the solvent; preferably wherein the composition comprises from 1 to 20 wt % of the plurality of mesoporous single crystals of titanium dioxide and from 1 to 40 mol % of the titanium di-isopropoxide bis(acetylacetonate) relative to the amount of titanium dioxide; or wherein the composition comprises from 5 to 15 wt % of the plurality of mesoporous single crystals of titanium dioxide and from 10 to 20 of the titanium di-isopropoxide bis(acetylacetonate) relative to the amount of titanium dioxide

The term “dispersed”, as used herein, refers to a state in which particles are uniformly dispersed in a medium (i.e. the solvent) to form a dispersion. The term “dispersion”, as used herein, may refer to a colloidal phase wherein the combination of the liquid solvent and the plurality of particles of a semiconductor material form a sol, or it may refer to a state wherein the plurality of particles of a semiconductor material form a suspension in the solvent. The distinction between a dispersion and a suspension can be the time it takes for the dispersed medium to separate; generally in the case of a dispersion, the dispersoid (that which is dispersed) will remain dispersed for long periods, whereas particles in a suspension may settle quickly. A suspension may also be known as “a coarse dispersion”.

If the process is a process for producing a compact layer of a semiconductor material, the plurality of particles of a semiconductor material may comprise a plurality of nanoparticles of anatase titanium dioxide; and the binder may comprise titanium di-isopropoxide bis(acetylacetonate). The solvent is typically anhydrous ethanol. Often, the process comprises disposing on the substrate a composition comprising the solvent, the plurality of nanoparticles of anatase titanium dioxide, and said titanium di-isopropoxide bis(acetylacetonate), wherein the plurality of nanoparticles of titanium dioxide are dispersed in the solvent and the titanium di-isopropoxide bis(acetylacetonate) is dissolved in the solvent. The composition may contain from 0.05 to 5 wt %, or from 0.1 to 5 wt % of a plurality of nanocrystals of anatase titanium dioxide. The composition may comprise from 1 to 40 mol %, from 5 to 35 mol %, or from 10 to 20 mol % of titanium di-isopropoxide bis(acetylacetonate) relative to the amount of titanium dioxide. The composition may contain from 0.05 to 5 wt % of a plurality of nanocrystals of anatase titanium dioxide and from 5 to 35 mol % of said titanium di-isopropoxide bis(acetylacetonate) relative to the amount of titanium dioxide.

The solvent may be removed by any process, such as allowing the solvent to evaporate, by heating or by vacuum evaporation. Preferably the solvent is removed by heating. The heating may involve heating the solvent at a temperature from 50° C. to 300° C. Typically, the removal of the solvent by heating comprises heating the solvent at a temperature from 100° C. to 200° C. The heating may comprise heating the solvent at a temperature of less than or equal to 150° C. For instance, the heating may comprise heating the solvent at a temperature of from 100° C. to 150° C. Thus, the entire process may be carried out at a temperature of less than or equal to 150° C. Heating the solvent will typically involve heating the composition comprising the solvent, for instance the as deposited film.

The removal of the solvent or solvents can occur over any period of time. Typically, it will occur over from 10 minutes to 24 hours. If the solvent or solvents are removed by heating or vacuum evaporation, this may be undertaken over from 10 minutes to 24 hours, from 10 minutes to 10 hours, from 15 minutes to 5 hours or from 20 minutes to 2 hours.

The term “heating”, as used herein, refers to the heating of the whole or part of the system in which the process of the invention is performed. In some cases, the substrate and the composition disposed on the substrate will be heated. In some cases, the solvent or solvents will be heated. The solvent may be heated by heating the substrate.

The invention also provides a layer of a semiconductor material obtainable by any of the above given processes according to the invention. Often, the layer of a semiconductor material obtainable by the process according to the invention is a mesoporous layer of a semiconductor material.

The invention also provides a process for producing a compact layer of a semiconductor material.

The inventors have also found that compact layers of a semiconductor material may be formed using a molecular compound comprising at least one metal or metalloid atom and one or more groups of formula OR, wherein each R is the same or different and is an unsubstituted or substituted C₁-C₈ hydrocarbyl group, and wherein two or more R groups may be bonded to each other. Accordingly, the invention provides a process for producing a compact layer of a semiconductor material, wherein the process comprises:

a) disposing on a substrate
i) a solvent, and
ii) a molecular compound comprising at least one metal or metalloid atom and one or more groups of formula OR, wherein each R is the same or different and is an unsubstituted or substituted C₁-C₈ hydrocarbyl group, and wherein two or more R groups may be bonded to each other; and

b) removing the solvent.

The two parts of this process for producing a compact layer of a semiconductor material may be performed together or separately in any order. Typically, part (a) is performed and then part (b) is performed. The two components (i) and (ii) may be disposed on the substrate simultaneously or consecutively, in either order. Typically the solvent and the molecular compound will be disposed on the substrate at the same time. Often, the molecular compound is dissolved in the solvent. This solution may then be disposed on the substrate.

Typically, an acid is present as a further component. For instance, step (a) may comprise disposing on the substrate a solvent, a molecular compound as defined, and an acid. Typically the acid is a mineral acid, and often the acid is H₂SO₄, HCl, HBr or HI. Preferably, the amount of acid present is from 0.5 to 5 wt %, from 0.5 to 2 wt % or from 0.75 to 1.5 wt %, where wt % here is relative to the total weight of the solvent, the molecular compound and the acid.

Additional solvents, substrates and molecular compounds may also be present. The molecular compound may comprise other groups as well as the one or more groups of formula OR, wherein each R is the same or different and is an unsubstituted or substituted C₁-C₈ hydrocarbyl group, and wherein two or more R groups may be bonded to each other.

The terms “disposing”, “substrate”, “solvent”, “molecular compound”, “metal atom”, “metalloid atom”, and “removing the solvent” are as defined above.

Often, a plurality of particles of a semiconductor material is included in the components disposed on the substrate. Thus, the process for producing a compact layer of a semiconductor material often comprises: a) disposing on a substrate i) a solvent, ii) a molecular compound comprising at least one metal or metalloid atom and one or more groups of formula OR, wherein each R is the same or different and is an unsubstituted or substituted C₁-C₈ hydrocarbyl group, and wherein two or more R groups may be bonded to each other, and iii) a plurality of particles of a semiconductor material; and b) removing the solvent

Often, the three components are disposed together as part of a composition. The process typically comprises: a) disposing on a substrate a composition comprising i) a solvent, ii) a molecular compound comprising at least one metal or metalloid atom and one or more groups of formula OR, wherein each R is the same or different and is an unsubstituted or substituted C₁-C₈ hydrocarbyl group, and wherein two or more R groups may be bonded to each other, and iii) a plurality of particles of a semiconductor material; and b) removing the solvent

The particles of a semiconductor material are often nanoparticles of the semiconductor material. The term “nanoparticle” is as defined above.

To obtain a compact layer of the semiconductor material, it is preferable to use small, low porosity particles of the semiconductor material. Compact layers may be used as blocking layers in semiconductor devices. Compact layers also function as electron selective contacts at the anode, or hole selective contacts at the cathode. It is desirable that a compact layer is dense and has a low porosity.

Thus, in one embodiment, the layer of a semiconductor material is a layer without open porosity. Sometimes, the layer of a semiconductor material is substantially non-porous. A layer which is substantially non-porous typically has a porosity of less than 0.1%.

The layer of a semiconductor material may be suitable for use as a selective contact for electron collection at an anode. The layer of a semiconductor material may be suitable for preventing recombination by electron leakage from an anode. The layer of a semiconductor material may be suitable for use as a selective contact for electron collection at an anode and/or the layer of a semiconductor material may be suitable for preventing recombination by electron leakage from an anode.

For a compact layer to have good transport properties, it is often desirable that the compact layer comprises crystalline material. Thus, the nanoparticles of the semiconductor material are often crystalline. The nanoparticles may be single crystals or polycrystals. The nanoparticles of the semiconductor material may be single crystals of the semiconductor material.

As explained above, it is preferable that a compact layer is produced using small nanoparticles of the semiconductor material in order to produce a dense layer. Thus, the nanoparticles of a semiconductor material may have an average particle size of less than or equal to 30 nm. The nanoparticles may have an average particle size of less than or equal to 20 nm, or less than or equal to 10 nm, for instance less than or equal to 5 nm. The nanoparticles of a semiconductor material often have an average particle size of less than or equal to 10 nm.

The amount of the plurality of particles of the semiconductor material may be an amount as described anywhere herein. Typically, in the process for producing a compact layer of a semiconductor material, the amount of the plurality of the particles of the semiconductor is from 0.01 to 40 wt %, from 0.02 to 10 wt %, from 0.05 to 5 wt %, or from 0.1 to 4 wt %. Often, the amount of the plurality of the particles of the semiconductor material is from 0.05 to 5 wt %

The amount of the molecular compound is typically from 1 to 40 mol %, from 5 to 35 from 10 to 30 mol %, or preferably from 15 to 25 mol %, relative to the amount of the semiconductor material. In some embodiments, the amount of the molecular compound is from 5 to 35 mol % relative to the amount of the semiconductor material.

The compact layer may be of any thickness, and may be of variable thickness across its extent. The compact layer of the semiconductor material often has a thickness of from 20 to 200 nm. For instance, the compact layer of the semiconductor material may have a thickness of from 10 to 1000 nm, from 20 to 200 nm, or from 20 to 100 nm. Often, it is preferable that the compact layer of the semiconductor material has a thickness of from 30 to 70 nm.

The process may further comprise producing the nanoparticles of a semiconductor material by a process comprising heating a composition comprising a precursor process solvent and a precursor metal halide compound.

In such an additional step of producing the nanoparticles of a semiconductor material by a process comprising heating a composition comprising a precursor process solvent and a precursor metal halide compound, the precursor metal halide compound typically decomposes in the solvent to produce a very fine suspension of nanoparticles of the semiconductor material. Thus, the precursor metal halide compound is typically a compound which decomposes to a semiconductor material upon heating in the precursor process solvent. Often, the precursor metal halide compound decomposes to form crystalline nanoparticles of a semiconductor material in the process precursor solvent.

The precursor process solvent typically comprises an alcohol selected from ethanol, propanol, isopropanol, butanol, sec-butanol, tert-butanol and benzyl alcohol. Often, the precursor process solvent is ethanol, propanol, isopropanol, butanol, sec-butanol, tert-butanol or benzyl alcohol. For instance, the precursor process solvent may comprise ethanol or benzyl alcohol, preferably benzyl alcohol. The precursor process solvent may be ethanol or benzyl alcohol, preferably benzyl alcohol. The alcohol is typically anhydrous. Thus, the solvent is often anhydrous ethanol or anhydrous benzyl alcohol.

The precursor metal halide compound is typically a compound of formula MX_{w}, wherein: M is a metal atom; each X is the same or different and is a halide atom; and w is an integer from 1 to 6. M may be any metal atom. M is selected from the elements of groups 3 to 12 of the periodic table of the elements, Al, Ga, In, Tl, Sn, Pb, Bi, B, Si, Ge, As, Sb and Te. Preferably, M is selected from Zr, V, Nb, Ti and Si. M may be selected from V, Nb, Ti and Si. Most preferably, M is Ti. Each X is a halide atom selected from F, Cl, Br and I. X may be Cl. Typically, w is from 1 to 4, or from 2 to 4. w is typically equal to the oxidation state of M. If the precursor metal halide compound comprises a metal atom M, the nanoparticles will comprise a semiconductor material which also comprises M.

Often, the precursor metal halide decomposes on heating in the precursor process solvent to form a metal oxide which is a semiconductor material. Thus, a precursor metal halide compound comprising titanium will form nanoparticles of a titanium oxide, in particular titanium dioxide.

Often the precursor compound is a metal chloride. The precursor metal halide compound may be titanium tetrachloride. Titanium tetrachloride may decompose in a precursor process solvent to form nanoparticles of titanium dioxide, in particular nanoparticles of anatase titanium dioxide.

Heating the composition comprises heating at a temperature of from 50° C. to 100° C., for instance from 70° C. to 90° C. The composition may be heated for from 1 to 24 hours, for instance from 5 to 15 hours. The composition is typically heated at a temperature of from 70° C. to 90° C. for a time of from 1 to 24 hours, or from 5 to 15 hours. After this time a suspension of nanoparticles of the semiconductor material will be formed. Precipitation of these particles may be caused by adding part of the suspension to another solvent, for instance diethyl ether. The resulting particles may be centrifuged, washed (optionally with acetone) and redispersed in a solvent, for instance anhydrous ethanol.

Nanoparticles of anatase titanium dioxide may be produced by a process comprising: (i) adding anhydrous TiCl₄ to anhydrous ethanol; (ii) adding the resulting solution to anhydrous benzyl alcohol; and (iii) heating the resulting composition at a temperature of from 50° C. to 100° C. for a time of from 1 to 24 hours.

Often, the particles of a semiconductor material are nanoparticles of anatase TiO₂. The particles of the semiconductor material may be nanoparticles of a semiconductor material obtainable by a process comprising heating a composition comprising a precursor process solvent and a precursor metal halide compound. The particles may be obtainable by this process, wherein the process is as further defined above.

The disposition of a component, solution or dispersion on the substrate may occur by spin-coating spray-coating, slot-die-coating, screen-printing, doctor blade coating, Gravure printing, inkjet printing, thermal evaporation, sputter coating, or any other vapour deposition. Preferably the disposition of a component occurs by spin-coating, slot-die-coating or spray coating.

The process for the production of a compact layer of a semiconductor material may be carried out effectively at low temperature. The process is typically carried out at a temperature less than or equal to 500° C., less than or equal to 400° C., or less than or equal to 300° C. The process may even be carried out at a temperature less than or equal to 200° C. or less than or equal to 150° C. Relatively low processing temperatures allow the process of the invention to be carried out in the presence of materials such as plastics which would deform and oxidize at higher temperatures. Low processing temperatures also allow the formation of multi-junction semiconductor devices which have the potential to degrade under more severe temperatures.

The substrate may be any substrate which is appropriate. The substrate may be composed of a single material or a mixture of materials, and may be homogeneous or inhomogeneous. The substrate may be planar or curved. The substrate may be smooth or rough. The substrate may be conducting, semiconducting or insulating, although the substrate is preferably conducting. Typically, the substrate is a substrate suitable for use in a semiconductor device. The term “substrate suitable for use in a semiconductor device”, as used herein, is as defined above. The substrate may comprise an electrode material. The electrode material may be a transparent conducting oxide. Preferably, the substrate is selected from ITO (indium tin oxide), FTO (fluorinated tin oxide), AZO (aluminium doped zinc oxide) or a metal. The metal may be any metal or mixture of metals selected from the elements of groups 3 to 12 of the periodic table of the elements, Al, Ga, In, Tl, Sn, Pb or Bi. Preferably the metal or mixture of metals is selected from Al, Fe, Steel, Cu, Pt, Ag, Au and Cu.

The compact layer of a semiconductor material may be produced to any thickness desired. Usually, the thickness of the compact layer of a semiconductor material produced will be from 10 and 500 nm, or from 20 to 100 nm. The thickness of the compact layer of a semiconductor material may be controlled by selecting the amount of the composition disposed on the substrate or by stopping disposing when the required thickness is reached.

The solvent present in the process for the production of a compact layer of a semiconductor material may be any solvent including those defined anywhere above. In one embodiment, the solvent is as organic solvent. Preferably, the solvent is an C₁-C₈-alcohol. In one embodiment the solvent is selected from methanol, ethanol, propanol, isopropanol, butanol, secbutanol or tertbutanol.

The molecular compound present in the process for producing a compact layer of a semiconductor material may be any molecular compound comprising at least one metal or metalloid atom and one or more groups of formula OR, wherein each R is the same or different and is an unsubstituted or substituted C₁-C₈ hydrocarbyl group, and wherein two or more R groups may be bonded to each other. For instance, it may be a molecular compound comprising at least one metal or metalloid atom and at least one C₁-C₈-alkoxide group or at least one acetylacetonate group.

In one embodiment, the molecular compound is a molecular compound with the formula [MO_{g}(OR)ₕZᵢ] wherein

M is a metal atom or a metalloid atom;

each R is the same or different and is an unsubstituted or substituted C₁-C₈ hydrocarbyl group, wherein two or more R groups may be bonded to each other;

each Z is the same or different and is a monodentate group;

g is 0 or an integer from 1 to 3;

h is an integer from 1 to 8;

i is 0 or an integer from 1 to 7 and

2g+h+i is equal to the valence of M.

The molecular compound may be a molecular compound with the formula [MO_{g}(OR)ₕ] wherein

M is a metal atom or a metalloid atom;

each R is the same or different and is an unsubstituted or substituted C₁-C₈ hydrocarbyl group, wherein two or more R groups may be bonded to each other;

g is 0 or an integer from 1 to 3;

h is an integer from 1 to 8, and

2g+h is equal to the valence of M.

Typically g is 0 or an integer from 1 to 3. For example, g is from 0 to 2, from 1 to 3, or 0, 2, or 3. Typically, h is an integer from 1 to 8. For example, h is from 1 to 7, from 1 to 6, from 1 to 5, from 2 to 7, from 2 to 6, from 2 to 5, from 1 to 4, or 1, 2, 3, 4, 5, 6, 7 or 8. Typically i is an integer from 1 to 7. For example, i is from 1 to 6, from 1 to 5, from 1 to 4, from 1 to 3, or 1, 2, 3, 4, 5, 6 or 7.

The terms “molecular compound”, “metal atom”, “metalloid atom”, “C₁-C₈ hydrocarbyl group”, “substituted”, “wherein two or more R groups may be bonded to each other”, “monodentate group” and “valence” are as defined above. The metal, metalloid, C₁-C₈ hydrocarbyl group, substituted C₁-C₈ hydrocarbyl group and monodentate group may be selected from any of those given above.

Examples of metals include Li, Na, K, Rb, Cs, Mg, Ca, Sr, Ba, Sc, Y, Lu, Ti, Zr, Hf, V, Nb, Ta, Cr, Mo, W, Mn, Re, Fe, Ru, Os, Co, Rh, Ir, Ni, Pd, Pt, Cu, Ag, Au, Zn, Cd, Hg, Al, Ga, In, Tl, Sn, Pb, and Bi. Typically, the metal atoms in the molecular compound present in the process for producing a compact layer of a semiconductor material are selected from those in groups 3 to 12 of the periodic table of the elements and Al, Ga, In, Tl, Sn, Pb and Bi. Typically, M is selected from the elements of groups 3 to 12 of the periodic table of the elements, Al, Ga, In, Tl, Sn, Pb, Bi, B, Si, Ge, As, Sb and Te. Preferably, M is selected from Zr, V, Nb, Ti and Si. M may be selected from V, Nb, Ti and Si. Preferably, M is Ti.

The molecular compound may comprise at least one C₁-C₈-alkoxide group or at least one 1,3-diketonate group. The molecular compound may comprise at least one C₁-C₈-alkoxide group and at least one 1,3-diketonate group.

The term “1,3-diketonate”, as used herein, refers to an anion obtainable by the deprotonation of a 1,3-diketone. The deprotonation will typically occur at the hydrogen adjacent to the two ketone groups (i.e. at the 2-position) as this is the most acidic hydrogen and leads to a stabilised anion. 1,3-diketonates may act as bidentate groups binding to a metal or metalloid atom through the two ketone oxygens. In some cases, 1,3-diketonates may be monodentate groups binding through the initially deprotonated carbon atom. The term “1,3-diketonate”, as used herein, refers to organic compounds comprising two ketone groups separated by a single carbon. Examples of 1,3-diketones include acetylacetone (pentane-2,4-dione: H₃CC(O)CH₂C(O)CH₃), 3-methylpentane-2,4-dione (H₃CC(O)CH(CH₃)C(O)CH₃) hexane-2,4-dione (H₃CC(O)CH₂C(O)CH₂CH₃) and heptane-3,5-dione (H₃CCH₂C(O)CH₂C(O)CH₂CH₃).

Typically, any 1,3-diketone or 1,3-diketonate will be a C₅-C₈-1,3-diketone or C₅-C₈-1,3-diketonate. The term “C₅-C₈-1,3-diketone”, as used herein, refers to a compound comprising two ketone groups separated by a single carbon and having 5, 6, 7 or 8 carbon atoms. The term “C₅-C₈-1,3-diketonate”, as used herein, refers to an anion obtained by the deprotonation of a C₅-C₈-1,3-diketone (typically at the carbon adjacent to both ketone groups). The C₅-C₈-1,3-diketone may be unsubstituted or substituted.

Typically, the molecular compound may be a metal or metalloid C₁-C₈-alkoxide. The term “metal or metalloid C₁-C₈-alkoxide”, as used herein, refers to metal or metalloid compounds comprising at least one C₁-C₈-alkoxide group (as defined above). In many cases, metal C₁-C₈-alkoxides comprise solely a metal or metalloid atom and one or more C₁-C₈-alkoxide groups. Examples of such compounds include titanium ethoxide [Ti(OCH₂CH₃)₄], titanium isopropoxide [Ti(OCH(CH₃)₂)₄], niobium ethoxide [Nb(OCH₂CH₃)₅], tetraethyl orthosilicate [Si(OCH₂CH₃)₄] and aluminium isopropoxide [Al(OCH(CH₃)₂)₃]. In other cases, metal or metalloid C₁-C₈-alkoxides comprise other ligands, in particular oxo ligands. An example of such compounds includes vanadium isopropoxide [VO(OCH(CH₃)₂)₃]. Preferably, the molecular compound is titanium isopropoxide.

Alternatively, the molecular compound may comprise an acetylacetonate group. Such compounds are known as metal (or metalloid) acetylacetonates. The following compounds are exemplary, amongst others, of metal acetylacetonates: titanium di-isopropoxide bis(acetylacetonate) [Ti(OCH(CH₃)₂)₂(acac)₂]; titanium oxide bis(acetylacetonate) [TiO(acac)₂]; zirconium acetyl acetonate [Zi(acac)₄]; vanadyl acetylacetonate [VO(acac)₂]; niobium (V) dichloro di-ethoxide acetylacetonate [NbCl₂(OCH₂CH₃)₂(acac)]; chromium (III) acetylacetonate [Cr(acac)₃]; molybdenum (III) acetylacetonate [Mo(acac)₃]; molybdenum (VI) di-oxo bis(acetylacetonate) [Mo(O)₂(acac)₂]; manganese (III) acetylacetonate [Mn(acac)₃]; tungsten (IV) tricarbonyl bis(acetylacetonate) [W(CO)₃(acac)₂]; iron (II) acetylacetonate [Fe(acac)₂]; iron (III) acetylacetonate [Fe(acac)₃]; ruthenium (III) acetylacetonate [Ru(acac)₃]; cobalt acetylacetonate [Co(acac)₃]; nickel (II) acetylacetonate [Ni(acac)₂]; copper acetylacetonate [Cu(acac)₂]; zinc acetylacetonate [Zn(acac)₂]; and aluminium acetylacetonate [Al(acac)₃]. In the case of compounds for which there are enantiomers, diastereomers, tautomers, salts or hydrates, any of these may be used. Reference to metal acetylacetonates also includes references to any dimeric, trimeric or oligimeric forms in which they might exist, such as the tetrameric form of anhydrous cobalt acetylacetonate, [Co(acac)₂]₄. Preferably, the molecular compound may be titanium di-isopropoxide bis(acetyl acetonate).

The amount of the molecular compound present may be from 1 to 60 wt %, or from 2 to 40 wt %, or preferably from 5 to 20 wt %. Here, “wt %” refers to the mass of the molecular compound as a percentage of the mass of the molecular compound and the solvent (an the optional acid, if present).

The removal of the solvent may be performed by allowing the solvent to evaporate, by heating or by vacuum evaporation. Preferably the solvent is removed by heating. The heating may involve heating at a temperature of from 50° C. to 300° C. Typically, the removal of the solvent by heating comprises heating the solvent at a temperature of from 100° C. to 200° C. Often, the heating comprises heating the solvent at a temperature of less than or equal to 150° C., for instance from 100° C. to 150° C. Heating the solvent will typically involve heating the composition comprising the solvent, for instance the as deposited film.

The removal of the solvent can occur over any period of time. Typically, it will occur over from 10 minutes to 24 hours. If the solvent is removed by heating or vacuum evaporation, this may be undertaken over from 10 minutes to 24 hours, from 10 minutes to 10 from 15 minutes to 5 hours or from 20 minutes to 2 hours.

The invention also provides a compact layer of a semiconductor material obtainable by any of the processes for producing a compact layer of a semiconductor material according to the invention as described above.

More than one compact layer of a semiconductor material may be formed by repeated application of the process for producing a compact layer according to the invention. Therefore a first compact layer of a first semiconductor material may be produced using a first binder compound, and then a second compact layer of a second semiconductor material may be disposed on the first compact layer by carrying out the process using a second binder compound. Any of the conditions or binders in this process may be as defined above. In particular, the process of the invention may first be performed to produce a first compact layer of a semiconductor material wherein the molecular compound is titanium isopropoxide, and then may be performed again wherein the binder is titanium di-isopropoxide bis(acetylacetonate) to produce a second compact layer of a semiconductor material disposed on the first compact layer.

The invention also provides a compact layer for a semiconductor device, which compact layer comprises a plurality of crystalline particles of a semiconductor material bound together by a decomposition product of a binder, wherein the binder is a molecular compound comprising at least one metal atom or metalloid atom. The decomposition product of the binder acts to bind the crystalline particles together, and thus improve electrical contact between the crystalline nanoparticles. The compact layer for a semiconductor may be obtained by a process described herein for producing a layer of a semiconductor material, or a compact layer of the semiconductor material. Thus, the compact layer for a semiconductor device may be obtainable by a process carried out at a temperature of less than or equal to 150° C.

The term “crystalline particle” as used herein refers to a particle which comprises greater than or equal to 80% of crystalline material. Often, a crystalline particle is a single crystal or a polycrystal.

In the compact layer for a semiconductor device according to the invention, the binder may be as defined anywhere hereinbefore. For instance the binder may be a compound of formula (1) or (2). The binder and the semiconductor material together may be as defined anywhere hereinbefore. In the compact layer for a semiconductor device according to the invention, the semiconductor material may be as defined anywhere hereinbefore. For instance, the semiconductor material may be an oxide or chalcogenide of a metal or metalloid element. The semiconductor material may be titanium dioxide.

The term “decomposition product”, as used herein, takes its usual meaning. Thus, a decomposition product of a binder is the compound or material which is obtained when the binder decomposes, for instance on heating or removal of a solvent. As the binder compound is a molecular compound comprising at least one metal atom or metalloid atom, the decomposition product will typically comprise the same at least one metal atom or metalloid atom. For instance, a binder which is a niobium compound will decompose to form a decomposition product which is a niobium compound or material, and equivalently for a binder which is a titanium compound. Often, the decomposition product will be a simple ionic or covalent inorganic compound. Thus, when a binder is a molecular compound comprising a metal atom or a metalloid atom M, the decomposition product will typically be an inorganic compound of formula [M]s[A]t, wherein [A] is an anion, [M] is a cation derived from M and s and t are each integers from 1 to 3. For instance, [A] may be selected from oxide and chalcogenide anions. Thus the decomposition product may be a metal oxide or a metal chalcogenide. The decomposition product of the binder is typically semiconducting.

The decomposition product of the binder is typically amorphous. The term “amorphous” takes its usual meaning in the art. Often, the decomposition product of the binder is an amorphous form of a semiconductor. The decomposition product of the binder is usually an amorphous form of a semiconductor as defined anywhere hereinbefore. Preferably, the decomposition product of a binder is an amorphous form of the semiconductor material, i.e. the decomposition product is an amorphous form of the same semiconductor material comprised in the particles of the semiconductor material. For instance, if the crystalline particles of the semiconductor material are crystalline particles of titania, the decomposition product of the binder is often an amorphous form of titania.

The particles of the semiconductor material may be as defined anywhere hereinbefore. The particles of the semiconductor material are often obtainable by a process comprising heating a composition comprising a precursor process solvent and a precursor metal halide compound. This process may be as described anywhere herein.

For a compact layer to have good transport properties, it is often desirable that the compact layer comprises crystalline material. Thus, the particles of the semiconductor material are crystalline particles which may be crystalline nanoparticles. The nanoparticles may be single crystals or polycrystals. The nanoparticles of the semiconductor material may be single crystals of the semiconductor material.

The nanoparticles of a semiconductor material may have an average particle size of less than or equal to 30 nm. The nanoparticles of a semiconductor material may have an average particle size of less than or equal to 20 nm, or less than or equal to 10 nm, for instance less than or equal to 5 nm. The nanoparticles of a semiconductor material often have an average particle size of less than or equal to 10 nm.

In some embodiments, the particles of the semiconductor material are nanoparticles of anatase TiO₂ and the decomposition product of a binder is amorphous titania.

The compact layer may be of any thickness, and may be of variable thickness across its extent. The compact layer usually has a thickness of from 5 to 500 nm. The compact layer often has a thickness of from 20 to 200 nm. For instance, the compact layer for a semiconductor device may have a thickness of from 10 to 1000 nm, from 20 to 200 nm, or from 20 to 100 nm. Often, it is preferable that the compact layer has a thickness of from 30 to 70 nm.

Thus, in one embodiment, the layer of a semiconductor material is a layer without open porosity. Compact layers do not typically have macropores or mesopores (which are as defined above). Thus, often, when the layer of a semiconductor material is a compact layer of a semiconductor material, the layer of a semiconductor material has substantially no macropores. The term “substantially no macropores”, as used herein, refers to a solid with a porosity, wherein less than or equal to 10% of said porosity is found in macropores. Less than or equal to 5% of said porosity may be found in macropores. Typically, less than or equal to 1% of said porosity may be found in macropores. Often, when the layer of a semiconductor material is a compact layer of a semiconductor material, the layer of a semiconductor material has substantially no macropores and substantially no mesopores. The term “substantially no macropores and substantially no mesopores”, as used herein, refers to a solid with a porosity, wherein less than or equal to 10% of said porosity is found in macropores and less than or equal to 10% of said porosity is found in mesopores. Less than or equal to 5% of said porosity may be found in macropores and less than or equal to 5% of said porosity may be found in mesopores. Typically, less than or equal to 1% of said porosity is found in macropores and less than or equal to 1% of said porosity is found in mesopores. As defined below, mesopores have widths (i.e. pore sizes) of from 2 nm to 50 nm and macropores have widths (i.e. pore sizes) of greater than 50 nm. A compact layer may comprise micropores. A compact layer may be microporous. Thus, the average pore size of the compact layer may be less than or equal to 2 nm. Sometimes, the layer of a semiconductor material is substantially non-porous. A layer which is substantially non-porous typically has a porosity of less than or equal to 5%, for instance less than or equal to 1%.

The compact layer for a semiconductor device may be suitable for use as a selective contact for electron collection at an anode. The compact layer for a semiconductor device may be suitable for preventing recombination by electron leakage from an anode. The compact layer for a semiconductor device may be suitable for use as a selective contact for electron collection at an anode and/or the compact layer for a semiconductor device may be suitable for preventing recombination by electron leakage from an anode.

Preferably, the compact layer has a conductivity of greater than or equal to 0.1×10⁻⁴ or greater than equal to 0.2×10⁻⁴ Scm⁻¹. For instance, the compact layer for a semiconductor device may have a conductivity of greater than or equal to 0.2×10⁻⁴ Scm⁻¹.

The compact layer is typically disposed on a substrate which comprises an electrode material. The substrate often comprises a layer of an electrode material. The compact layer is often in contact with the layer of the electrode material. Thus, the compact layer is often disposed on a substrate which comprises a layer of a transparent conducting oxide, preferably wherein the transparent conducting oxide is selected from ITO, FTO and AZO. The transparent conducting oxide may be FTO. The electrode material may be disposed on an inert substrate, for instance glass.

The invention also provides a semiconductor device which comprises a compact layer for a semiconductor device according to the invention. Thus, the invention provides a semiconductor device which comprises a compact layer for a semiconductor device, which compact layer comprises a plurality of crystalline particles of a semiconductor material bound together by a decomposition product of a binder, wherein the binder is a molecular compound comprising at least one metal atom or metalloid atom. The compact layer for a semiconductor may be as described anywhere herein.

Typically, the semiconductor device further comprises a layer of a further semiconductor material or a layer of a dielectric material, which layer of a further semiconductor material or a layer of a dielectric material is disposed on the compact layer. The further semiconductor material may be a semiconductor as defined anywhere herein. For instance, the further semiconductor may be a perovskite or crystalline silicon. When the device comprises a perovskite, the perovskite may be a metal halide perovskites are described in WO 2013/171517, WO 2013/171518, and WO 2013/171520, the entire contents of which are incorporated herein by reference. The perovskite may be as defined anywhere herein. For instance the perovskite may be a mixed halide perovskite. The dielectric material may be as defined anywhere herein. For instance, the dielectric material may comprise alumina.

The layer of a further semiconductor material or the layer of a dielectric material is often mesoporous. For instance, the layer of a further semiconductor material may be a mesoporous layer of titania, or the layer of a dielectric material may be a mesoporous layer of alumina. Mesoporous layer may be present in sensitized devices. Thus the semiconductor device may further comprise a layer of a dye or a layer of a photoactive material. The semiconductor device may further comprises a layer of a semiconducting perovskite. The layer of the semiconducting perovskite may be disposed on a mesoporous layer, or it may be disposed directly on the compact layer. The semiconducting perovskite may be disposed on a layer of alumina having a thickness of less than 40 nm, wherein the thickness of the layer of the semiconducting perovskite may be greater than 40 nm, for instance from 100 to 300 nm. The thickness of the layer of the semiconducting perovskite may be greater than 40 nm, for instance from 100 to 700 nm.

Often, the semiconductor device may further comprise a layer of a semiconducting perovskite without open porosity. The layer of a semiconducting perovskite may form a planar heterojunction with the compact layer and any additional layer disposed on the layer of the perovskite.

Typically, the semiconductor device further comprises a layer of a hole transporter material. The hole transporter material may be as described anywhere herein. For instance, the hole transporter material may comprise spiro-OMeTAD.

The semiconductor device usually further comprises a layer of a second electrode material. The layer of the second electrode material may comprise an electrode material as defined anywhere herein. The second electrode material often comprises a metal or a transparent conducting oxide. Preferably the second electrode material comprises a metal. The layer of a second electrode material is typically from 5 to 200 nm thick. The layer of a second electrode material may be from 10 to 200 nm thick. The layer of a second electrode material is typically a layer of silver or gold.

The semiconductor device often comprises: I. a layer of a transparent conducting oxide, preferably wherein the transparent conducting oxide is FTO; II. the compact layer for a semiconductor device according to the invention; III. a mesoporous layer of a dielectric material, preferably wherein the dielectric material comprises alumina; IV. a layer of a photoactive perovskite, preferably wherein the photoactive perovskite is a metal halide perovskite, for instance CH₃NH₃PbICl₂; V. a layer of a hole transporting material, preferable wherein the hole transporting material comprises spiro-OMeTAD; and VI. a layer of a second electrode material, preferably wherein the second electrode material is a metal. Typically, the device comprises these layers in this order, i.e. I to VI. The device may comprise additional layers disposed between any of the layers I to VI.

The semiconductor device is often a photovoltaic device and the device may have short circuit current (Jsc) of greater than or equal to 15 mAcm-2 and/or a power conversion efficiency (η) of greater than or equal to 10% and/or a fill factor (FF) of greater than or equal to 0.6 and/or a series resistance (Rs) of less than or equal to 10 Ωcm². Each of these parameters is well know to the skilled person. They may be measured or estimated easily using standard techniques.

The invention also provides semiconductor devices which comprise either at least one layer of a semiconductor material obtainable by a process of the invention or at least one compact layer of semiconductor material obtainable by a process of the invention. A semiconductor device according to the invention may comprise both at least one layer of a semiconductor material obtainable by a process of the invention and at least one compact layer of semiconductor material obtainable by a process of the invention. The term “semiconductor device”, as used herein, refers to a device comprising a functional component which comprises a semiconductor material. This term may be understood to be synonymous with the term “semiconducting device”.

Typically, the semiconductor device is a photovoltaic device, a solar cell, a photo detector, a light-sensitive transistor, a phototransistor, a solid state triode, a battery, a battery electrode, a capacitor, a super-capacitor, a light-emitting device, or a light-emitting diode. The semiconductor device may be an optoelectronic device. The term “optoelectronic device”, as used herein, refers to devices which source, control or detect light. Light is understood to include any electromagnetic radiation. Examples of optoelectronic devices include photodiodes (including solar cells), phototransistors, photomultipliers, photoresistors, and light emitting diodes.

In one embodiment, the semiconductor device according to the invention is a perovskite solar cell, a dye-sensitized solar cell, a perovskite-sensitized solar cell, an extremely thin absorber cell (G. Hodes et al. “All-Solid-State, Semiconductor-Sensitized Nanoporous Solar Cells”, Accounts of Chemical Research 45, 705-713 (2012)) or a quantum dot sensitized solar cell (Kamat, P. V. “Quantum Dot Solar Cells. Semiconductor Nanocrystals as Light Harvesters”, J. Phys. Chem. C 112, 18737-18753 (2008)). Often, the semiconductor device is a dye-sensitized solar cell or a perovskite sensitized solar cell. A dye-sensitized or perovskite-sensitized solar cell according to the invention may be a solid state dye-sensitized or solid-state perovskite-sensitized solar cell. Dye-sensitized solar cells and perovskite-sensitized solar cells are examples of sensitized solar cells. In a sensitized solar cell there is a layer of a sensitizing material which interacts with photons such as a dye or a photoactive material (e.g. a semiconducting perovskite or semiconductor).

The semiconductor device according to the invention may comprise a plurality of other layers and components. Other components or layers include electrode materials, electron transporter materials and hole transporter materials. Particularly in the case of a dye-sensitized solar cell, the device will also comprise a dye and a hole transporter layer, or in the case of a perovskite-sensitized solar cell, the device will also comprise a semiconducting perovskite and a hole transporter layer or an electron transporter layer.

The hole transporter layer may comprise any hole transporter material, for example an organic hole transporter material or an inorganic hole transporter material. Examples of organic hole transporter materials include spiro-OMeTAD (2,2′,7,7′-tetrakis-(N,N-di-pmethoxyphenylamine) 9,9′-spirobifluorene)), P3HT (poly(3-hexylthiophene)), PCPDTBT (Poly[2,1,3-benzothiadiazole-4,7-diyl[4,4-bis(2-ethylhexyl)-4H-cyclopenta[2,1-b:3,4-b′]dithiophene-2,6-diyl]]), PVK (poly(N-vinylcarbazole)), Li-TFSI (lithium bis(trifluoromethanesulfonyl)imide) or tBP (tert-butylpyridine). Preferably hole transport material is spiro-OMeTAD (2,2′,7,7′-tetrakis-(N,N-di-pmethoxyphenylamine) 9,9′-spirobifiuorene)), or polyethelenedioxythiophene (PEDOT), optionally doped with poly-styrene sulphonate (PSS), such as PEDOT:PSS. Typically, an inorganic hole transporter material will be a p-type semiconductor. An example of an inorganic hole transport material is an oxide hole transport material, such as an oxide of nickel, vanadium, copper, tungsten or molybdenum (e.g. MoO₃, V₂O₅ or W₂O₃); CuI, CuBr, CuSCN, Cu₂O, CuO or CIS; a perovskite; amorphous Si; a p-type group IV semiconductor, a p-type group III-V semiconductor, a p-type group II-VI semiconductor, a p-type group I-VII semiconductor, a p-type group IV-VI semiconductor, a p-type group V-VI semiconductor, and a p-type group II-V semiconductor, which inorganic material may be doped or undoped.

The hole transporter material of the invention may comprise additional components. These additional components may include dopants. In particular, the hole transporter material may additionally comprise a chemical p-dopant, such as F4-TCNQ, or ionic dopants such as Li-TFSI, and other additives such as tBP.

A sensitized solar cell will typically comprises the following layers (and may comprise one or more further layers between each of the given layers):

I. a layer of a first electrode material;

II. optionally a compact layer of a semiconductor material;

III. a layer of a semiconductor material (which is preferably mesoporous);

IV. a layer of a sensitizer (e.g. a dye or a semiconducting perovskite);

V. optionally a hole transporter layer;

VI. optionally a further compact layer of a semiconductor material; and

VII. a layer of a second electrode material.

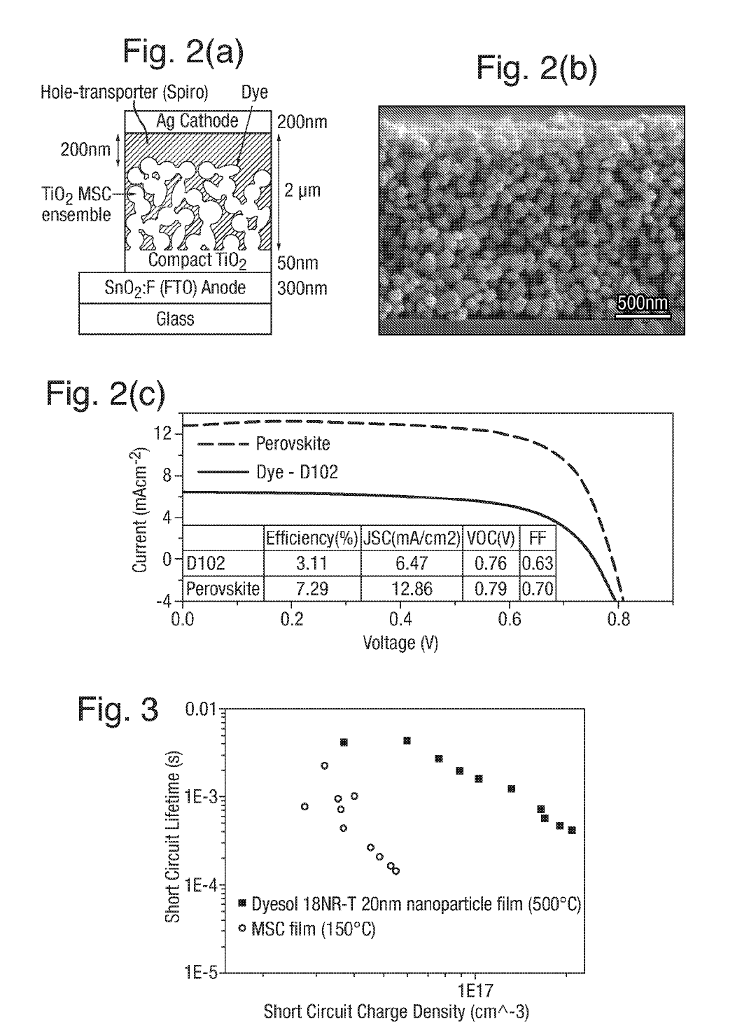

FIG. 2(a) contains a schematic of a dye-sensitized solar cell. A sensitized solar cell may comprise several stacks of these layers and may be a multi-junction sensitised solar cell.

In a dye-sensitized solar cell, the dye may be selected from any dye suitable for use in a dye-sensitized solar cell. These are well known to the skilled person. An example of a suitable dye is the indolene dye D102, an organic “push-pull” dye such as those described in T. Horiuchi et al. (“High Efficiency of Dye-Sensitized Solar Cells Based on Metal-Free Indoline Dyes”, J. Am. Chem. Soc. 126, 12218-12219 (2004)), a ruthenium complex dye, an organic dyes such as those described in W. Zeng, et al. (“Efficient Dye-Sensitized Solar Cells with an Organic Photosensitizer Featuring Orderly Conjugated Ethylenedioxythiophene and Dithienosilole Blocks”, Chem. Mater. 22, 1915-1925 (2010)) or a rylene based dye such as those described in US 2012/0017995.

In a perovskite-sensitized solar cell, the perovskite will be a semiconducting perovskite. Usually, the perovskite is a light-absorbing material. The perovskite semiconductor employed may have a band gap of equal to or less than 3.0 eV. Often, the perovskite is a perovskite compound of formula [A][B][X]3 wherein: [A] is at least one organic cation; [B] is at least one metal cation; and [X] is at least one anion. The term “organic cation” refers to a cation comprising carbon. The cation may comprise further elements, for example, the cation may comprise hydrogen, nitrogen or oxygen. Typically, the cation will be a quaternary ammonium ion.

The perovskite may alternatively be a compound of formula AB[X]₃ wherein A is an organic cation, B is a metal cation and [X] is two or more different anions. Usually, [X] is two or more different halide anions. The perovskite may also be a compound of formula ABX_{3-y}X′_{y} wherein A is an organic cation, B is a metal cation, X is a first halide anion, X′ is a second halide anion which is different from the first halide anion, and y is from 0.05 to 2.95. For example, the perovskite may be a perovskite of formula CH₃NH₃PbI_{3-y}Cl_{y}.

In the cases of [A][B][X]₃, AB[X]₃, and ABX_{3-y}X′_{y} the first cation (A) is an organic cation. The second cation (B) may be selected Ca²⁺, Sr²⁺, Cd²⁺, Cu²⁺, Ni²⁺, Mn²⁺, Fe²⁺, Co²⁺, Pd²⁺, Ge²⁺, Sn²⁺, Pb²⁺, Sn²⁺, Yb²⁺ and Eu²⁺. Usually, the second cation is selected from Sn²⁺ and Pb²⁺.

Usually, the organic cation has the formula (R₁R₂R₃R₄N), wherein:
R₁ is hydrogen, unsubstituted or substituted C₁-C₂₀ alkyl, or unsubstituted or substituted aryl;
R₂ is hydrogen, unsubstituted or substituted C₁-C₂₀ alkyl, or unsubstituted or substituted aryl;
R₃ is hydrogen, unsubstituted or substituted C₁-C₂₀ alkyl, or unsubstituted or substituted aryl; and
R₄ is hydrogen, unsubstituted or substituted C₁-C₂₀ alkyl, or unsubstituted or substituted aryl.

Mainly, in the organic cation, R₁ is hydrogen, methyl or ethyl, R₂ is hydrogen, methyl or ethyl, R₃ is hydrogen, methyl or ethyl, and R₄ is hydrogen, methyl or ethyl. For instance R₁ may be hydrogen or methyl, R₂ may be hydrogen or methyl, R₃ may be hydrogen or methyl, and R₄ may be hydrogen or methyl.

In the case of the organic cation, a C₁-C₂₀ alkyl group is an unsubstituted or substituted, straight or branched chain saturated hydrocarbon radical. Typically it is C₁-C₁₀ alkyl, for example methyl, ethyl, propyl, butyl, pentyl, hexyl, heptyl, octyl, nonyl or decyl, or C₁-C₆ for example methyl, ethyl, propyl, butyl, pentyl or hexyl, or C₁-C₄ alkyl, for example methyl, ethyl, i-propyl, n-propyl, t-butyl, s-butyl or n-butyl.

When an alkyl group in the organic cation is substituted it typically bears one or more substituents selected from substituted or unsubstituted C₁-C₂₀ alkyl, substituted or unsubstituted aryl (as defined herein), cyano, amino, C₁-C₁₀ alkylamino, di(C₁-C₁₀)alkylamino, arylamino, diarylamino, aryl alkyl amino, amido, acylamido, hydroxy, oxo, halo, carboxy, ester, acyl, acyloxy, C₁-C₂₀ alkoxy, aryloxy, haloalkyl, sulfonic acid, sulfhydryl (i.e. thiol, —SH), C₁-C₁₀ alkylthio, arylthio, sulfonyl, phosphoric acid, phosphate ester, phosphonic acid and phosphonate ester. Examples of substituted alkyl groups include haloalkyl, hydroxyalkyl, aminoalkyl, alkoxyalkyl and alkaryl groups. The term alkaryl, as used herein, pertains to a C₁-C₂₀ alkyl group in which at least one hydrogen atom has been replaced with an aryl group. Examples of such groups include, but are not limited to, benzyl (phenylmethyl, PhCH₂—), benzhydryl (Ph₂CH—), trityl (triphenylmethyl, Ph₃C—), phenethyl (phenylethyl, Ph-CH₂CH₂—), styryl (Ph-CH═CH—), cinnamyl (Ph-CH═CH—CH₂—).

Typically a substituted alkyl group carries 1, 2 or 3 substituents, for instance 1 or 2.

In the case of the organic cation, an aryl group is a substituted or unsubstituted, monocyclic or bicyclic aromatic group which typically contains from 6 to 14 carbon atoms, preferably from 6 to 10 carbon atoms in the ring portion. Examples include phenyl, naphthyl, indenyl and indanyl groups. An aryl group is unsubstituted or substituted. When an aryl group as defined above is substituted it typically bears one or more substituents selected from C₁-C₆ alkyl which is unsubstituted (to form an aralkyl group), aryl which is unsubstituted, cyano, amino, C₁-C₁₀ alkylamino, di(C₁-C₁₀)alkylamino, arylamino, diarylamino, arylalkylamino, amido, acylamido, hydroxy, halo, carboxy, ester, acyl, acyloxy, C₁-C₂₀ aryloxy, haloalkyl, sulfhydryl (i.e. thiol, —SH), C₁₋₁₀alkylthio, arylthio, sulfonic acid, phosphoric acid, phosphate ester, phosphonic acid and phosphonate ester and sulfonyl. Typically it carries 0, 1, 2 or 3 substituents. A substituted aryl group may be substituted in two positions with a single C₁-C₆ alkylene group, or with a bidentate group represented by the formula —X—(C₁-C₆)alkylene, or —X—(C₁-C₆)alkylene-X—, wherein X is selected from O, S and NR, and wherein R is H, aryl or C₁-C₆ alkyl. Thus a substituted aryl group may be an aryl group fused with a cycloalkyl group or with a heterocyclyl group. The ring atoms of an aryl group may include one or more heteroatoms (as in a heteroaryl group). Such an aryl group (a heteroaryl group) is a substituted or unsubstituted mono- or bicyclic heteroaromatic group which typically contains from 6 to 10 atoms in the ring portion including one or more heteroatoms. It is generally a 5- or 6-membered ring, containing at least one heteroatom selected from O, S, N, P, Se and Si. It may contain, for example, 1, 2 or 3 heteroatoms. Examples of heteroaryl groups include pyridyl, pyrazinyl, pyrimidinyl, pyridazinyl, furanyl, thienyl, pyrazolidinyl, pyrrolyl, oxazolyl, oxadiazolyl, isoxazolyl, thiadiazolyl, thiazolyl, isothiazolyl, imidazolyl, pyrazolyl, quinolyl and isoquinolyl. A heteroaryl group may be unsubstituted or substituted, for instance, as specified above for aryl. Typically it carries 0, 1, or 3 substituents.

In one embodiment, the perovskite is a perovskite compound selected from CH₃NH₃PbI₃, CH₃NH₃PbBr₃, CH₃NH₃PbCl₃, CH₃NH₃PbF₃, CH₃NH₃PbBrI₂, CH₃NH₃PbBrCl₂, CH₃NH₃PbIBr₂, CH₃NH₃PbICl₂, CH₃NH₃PbClBr₂, CH₃NH₃PbI₂Cl, CH₃NH₃SnBrI₂, CH₃NH₃SnBrCl₂, CH₃NH₃SnF₂Br, CH₃NH₃SnIBr₂, CH₃NH₃SnICl₂, CH₃NH₃SnF₂I, CH₃NH₃SnClBr₂, CH₃NH₃SnI₂Cl and CH₃NH₃SnF₂Cl. The perovskite may be selected from CH₃NH₃PbBrI₂, CH₃NH₃PbBrCl₂, CH₃NH₃PbIBr₂, CH₃NH₃PbICl₂, CH₃NH₃PbClBr₂, CH₃NH₃PbI₂Cl, CH₃NH₃SnBrI₂, CH₃NH₃SnBrCl₂, CH₃NH₃SnF₂Br, CH₃NH₃SnIBr₂, CH₃NH₃SnICl₂, CH₃NH₃SnF₂I, CH₃NH₃SnClBr₂, CH₃NH₃SnI₂Cl and CH₃NH₃SnF₂Cl.

Typically, the perovskite is selected from CH₃NH₃PbBrI₂, CH₃NH₃PbBrCl₂, CH₃NH₃PbIBr₂, CH₃NH₃PbICl₂, CH₃NH₃PbClBr₂, CH₃NH₃PbI₂Cl, CH₃NH₃SnF₂Br, CH₃NH₃SnICl₂, CH₃NH₃SnF₂I, CH₃NH₃SnI₂Cl and CH₃NH₃SnF₂Cl.

The perovskite may be a perovskite compound selected from CH₃NH₃PbI₃, CH₃NH₃PbBr₃, CH₃NH₃PbCl₃, CH₃NH₃PbF₃, CH₃NH₃PbBrxI₃₋ₓ, CH₃NH₃PbBrxCl₃₋ₓ, CH₃NH₃PbIxBr₃₋ₓ, CH₃NH₃PbIxCl₃₋ₓ, CH₃NH₃PbClxBr₃₋ₓ, CH₃NH₃PbI₃₋ₓClₓ, CH₃NH₃SnI₃, CH₃NH₃SnBr₃, CH₃NH₃SnCl₃, CH₃NH₃SnF₃, CH₃NH₃SnBrI₂, CH₃NH₃SnBrxI₃₋ₓ, CH₃NH₃SnBrxCl₃₋ₓ, CH₃NH₃SnF₃₋ₓBrₓ, CH₃NH₃SnIₓBr₃₋ₓ, CH₃NH₃SnIₓCl₃₋ₓ, CH₃NH₃SnF₃₋ₓIₓ, CH₃NH₃SnClₓBr₃₋ₓ, CH₃NH₃SnI₃₋ₓClₓ and CH₃NH₃SnF₃₋ₓClₓ, where x is from 0.01 to 2.99. x is often from 0.05 to 2.95. For instance, x may be from 0.5 to 2.5, from 0.75 to 2.25, or from 1 to 2.

The invention also provides a process for producing a semiconductor device comprising producing a layer of a semiconductor material by a process according to the invention. The layer of a semiconductor material produced may be mesoporous.

Generally, a process for producing a semiconductor device may include some or all of the following steps in any combination and in any order:
A. providing a transparent conducting oxide-coated glass sheet;
B. etching the sheets with zinc powder and HCl (2M) to obtain an electrode pattern;
C. washing the sheets (optionally with soap, deionized water, acetone, and/or methanol);
D. treating the sheets with an oxygen plasma (optionally for from 5 to 10 minutes);
E. spin-coating a composition comprising a molecular compound as defined above and a solvent (optionally also comprising a mineral acid, e.g. HCl or HBr);
F. drying the sheet to form a compact layer of a semiconductor material (optionally by heating at a temperature between 100° C. and 200° C., optionally for from 2 to 60 minutes);
G. spin-coating onto the compact layer (or any further layer disposed on the surface of the compact layer) a composition comprising a plurality of particles of a semiconductor material, a binder as defined above, and a solvent;
H. drying the spin-coated layer by heating (optionally by heating at a temperature of from 100° C. to 200° C., and optionally for from 2 to 60 minutes);
I. sensitizing the layer of a semiconductor material by immersing it in a solution of a dye (optionally wherein the dye is at a concentration of from 0.1 to 0.3 mM in a 1:1 volume ratio of tertbutanol and acetonitrile; optionally wherein the immersion is carried out for from 5 minutes to 5 hours); or sensitizing the layer of a semiconductor material by disposing a layer of a photoactive material (optionally wherein the photoactive material is a photoactive perovskite);
J. spin-coating (optionally using chlorobenzene as a solvent) a hole transporter material;
K. exposing the device to air (optionally for a minimum period of 4 hours);
L. drying the device by heating; and
M. depositing an electrode material by vacuum deposition (optionally wherein the electrode material is silver and the thickness of the electrode material is from 10 to 500 nm).

Typically, the process for producing a semiconductor device may comprise steps A to J, optionally step K, and steps L and M, and in that order. The process may also comprise steps E to J.

The invention provides a process for producing a semiconductor device comprising a layer of a semiconductor material, wherein the process comprises producing said layer of a semiconductor material by:

p) disposing on a substrate
i) a plurality of particles of a semiconductor material,
ii) a binder, wherein the binder is a molecular compound comprising at least one metal atom or metalloid atom, and
iii) a solvent; and

q) removing the solvent.

Typically, the process for producing said layer of a semiconductor material is as further defined anywhere above. Here, the substrate may comprise a first electrode material. Alternatively, the substrate may comprise a first electrode material and, disposed on the first electrode material, a compact layer of a semiconductor material, and wherein step (p) comprises disposing the plurality of particles of a semiconductor material, the binder and the solvent, on said compact layer of a semiconductor material. The plurality of particles of a semiconductor material, the binder and the solvent may be any of those as defined above.

The process for producing a semiconductor device may further comprise, prior to step (p):
o) producing said substrate by disposing on the first electrode material a compact layer of a semiconductor material.

Typically, step (o) comprises:

a) disposing on the first electrode material
i) a solvent, and
ii) a molecular compound comprising at least one metal or metalloid atom and one or more groups of formula OR, wherein each R is the same or different and is an unsubstituted or substituted C₁-C₈ hydrocarbyl group, and wherein two or more R groups may be bonded to each other;

b) and removing the solvent.

Here, steps (a) and (b) may be as further defined above.

Typically, the process for producing a semiconductor device further comprises:
r) disposing a dye on the layer of a semiconductor material produced in steps (p) and (q), to produce a layer of a dye-sensitized semiconductor material; or alternatively, the process for producing a semiconductor device further comprises:
r) disposing a layer of a photoactive semiconductor material on the layer of a semiconductor material produced in steps (p) and (q).
   Preferably, the photoactive semiconductor material is a perovskite. The perovskite may be any of the perovskites defined above.

Often, the process will further comprise:
s) disposing a layer of a hole transporter material on the dye-sensitized semiconductor material or the photoactive semiconductor material produced in step (r).

The process may further comprise:
t) disposing a layer of a second electrode material on the layer of a hole transporter material.

The second electrode material may be any electrode material as defined above. Preferably the second electrode is a metal or a transparent conducting oxide. Typically the second electrode material will be Ag. The disposition of the second electrode material may occur by vacuum deposition.

The invention also provides a process for producing a semiconductor device comprising a compact layer of a semiconductor material, wherein the process comprises producing said compact layer of a semiconductor material by:

p) disposing on a substrate
i) a molecular compound comprising at least one metal or metalloid atom and one or more groups of formula OR, wherein each R is the same or different and is an unsubstituted or substituted C₁-C₈ hydrocarbyl group, and wherein two or more R groups may be bonded to each other; and
ii) a solvent; and

q) removing the solvent.

Typically, producing said compact layer of a semiconductor material is as further defined above. For instance, the process may comprise producing said compact layer of a semiconductor material by:

p) disposing on a substrate a composition comprising
i) a solvent,
ii) a molecular compound comprising at least one metal or metalloid atom and one or more groups of formula OR, wherein each R is the same or different and is an unsubstituted or substituted C₁-C₈ hydrocarbyl group, and wherein two or more R groups may be bonded to each other, and
iii) a plurality of particles of a semiconductor material; and

q) removing the solvent

In one embodiment, the process further comprises
r) producing a layer of a semiconductor material on the compact layer of a semiconductor material;
   preferably wherein producing said layer of a semiconductor material is as defined above; optionally wherein the layer of a semiconductor material is a mesoporous layer.

Often, the process further comprises:
s) disposing a dye on the layer of a semiconductor material produced in step (r) to produce a layer of a dye-sensitized semiconductor material.

Alternatively, the process may further comprise:
s) disposing a layer of a photoactive material on the layer of a semiconductor material produced in step (r).
   preferably wherein the photoactive material is a perovskite.

The process may further comprise:
t) disposing a layer of a hole transporter material on the dye-sensitized semiconductor material or the layer of a photoactive semiconductor material.

The process typically further comprises:
u) disposing a layer of a second electrode material on the layer of the hole transporter material.

Any of the components or process steps used in a process for producing a semiconductor device according to the invention may be as defined above.

When a compact layer is disposed on a substrate, the substrate may comprise a layer of a semiconductor material. For instance, a process according to the invention may comprise disposing a compact layer of a layer of a semiconductor material, for instance silicon.

The term “photoactive”, as used herein, refers to a material which is capable of responding to light photoelectrically.

The layer of a dye may be disposed by any means. Typically, the dye is disposed on a substrate by immersing the substrate in a solution comprising the dye for a period of time (e.g. from 10 minutes to 2 hours, or from 30 to 90 minutes). Typically, the solution containing the dye will have as a solvent any of the solvents defined above, preferably, however, the solvent will comprise tert-butanol and acetonitrile. The tert-butanol and acetonitrile may have a volume ratio of from 0.1:1 to 10:1 or from 0.5:1 to 2:1. The concentration of the dye in this solution is typically from 0.05 to 10 mM, from 0.05 to 1 mM or from 0.1 to 0.5 mM.

Any step in which a layer of a hole transporter material is disposed on a substrate may be performed by any method. Typically the hole transporter material is disposed as a solution in an any of the above defined solvents. Preferably the solvent is a halogenated hydrocarbon such as chlorobenzene. The solution of the hole transporter material is preferably disposed by spin-coating, but may be disposed by any other suitable method such as spray-coating, slot-die-coating, thermal evaporation, sputtering, or vapour deposition. The solution comprising the hole transporter material may comprise additional components, in particular these additional components may be LiTFSI and tBP. Preferably, the solution will comprise spiro-OMeTAD (optionally at a concentration of from 100 to 300 mg/mL), Li-TFSI (optionally at from 0.5 to 1.5 molar ratio to the spiro-OMeTAD) and tBP (optionally at from 0.05 to 0.25 molar ratio to the spiro-OMeTAD).

The combined thickness of the layer of a semiconductor material and the layer of a hole transporter material is usually from 100 nm to 10 μm, from 500 nm to 5 μm. Preferably, the combined thickness is from 1 to 3 μm. The difference between the combined thickness of the layer of a semiconductor material and the layer of the hole transporter material and the thickness of the layer of a semiconductor material alone is typically from 10 to 500 nm, or preferably from 150 to 250 nm.

If the process comprises a step of disposing a layer of a photoactive material such as a perovskite (for example, as defined above) onto a substrate, this layer may be disposed in any way. Typically the layer is disposed by solution deposition, i.e. depositing a solution of the photoactive material onto the layer below and performing a solvent removal step. Alternatively the layer may be deposited by vapour deposition, i.e. by exposure to a vapour comprising the photoactive material or reagents suitable for producing the photoactive material. The photoactive material may also be disposed by sputtering, slot-die-coating or spin-coating. Typically, it is disposed by spin-coating a solution of the material then performing a solvent removal step.

If the process comprises a step of disposing a layer of an electrode material this may be performed by any suitable process. In particular, in the case of the disposition of a second electrode material, this may be performed by vacuum deposition. If vacuum deposition is used, it will typically occur under a high vacuum (e.g. a pressure of less than 10⁻⁵ mbar). The first or second electrode materials may be any electrode material as defined above. Preferably, the first electrode material is a transparent conducting oxide such as ITO, FTO or AZO. The thickness of the layer of the first electrode material is usually from 100 to 1000 or 100 to 500 nm, and preferably from 200 to 400 nm.

The second electrode material is preferably a metal. This metal will typically be Ag, Au or Pt. In one embodiment, the second electrode material is disposed by depositing a layer of Ag by vacuum deposition. The thickness of the layer of the second electrode material deposited may be from 10 to 1000 nm, from 50 to 500 nm, or from 200 to 400 nm.

Throughout this specification, the terms “a”, “an” and “the”, as used herein, may refer to the singular or the plural of the term following “a”, “an” and “the”.

The invention is further described in the following example.

### Example

### Mesoporous Layer Production

### Low Temperature Solar Cell Assembly:

This example shows that effective high-surface area (mesoporous) layers of a semiconductor material can be produced at low temperature.

FTO-coated glass sheets (15 Ωcm⁻¹ Pilkington) were etched with zinc powder and HCl (2M) to obtain the required electrode pattern. The sheets were then washed with soap (2% Hellmanex in water), deionized water, acetone, and methanol, and finally treated under oxygen plasma for 10 minutes.

### Compact Layer Formation

A TiO₂ compact layer was first deposited by spin-coating on a clean fluorine-doped tin oxide (FTO) coated glass substrate. The compact layer spin-coating solution was prepared by adding 0.71 g titanium isopropoxide and 0.07 g HCl to 8 mL of ethanol. The compact layer was then dried at 150° C. for 30 minutes.

### Semiconductor Layer Production

The TiO₂ MSC film ensemble was deposited by spin-coating a solution of MSCs (300 nm crystal size, 50 nm pore size) dispersed in ethanol at 10 wt % concentration with the addition of 15 mol % titanium di-isopropoxide bis(acetylacetonate) relative to TiO₂. The substrates were dried at 150° C. and subsequently immersed in a sensitizing solution containing the indolene organic dye (D102, 0.2 mM in a 1:1 volume ratio of tert-butanol and acetonitrile) for one hour.

### Device Construction

After sensitization, a Spiro-OMeTAD hole transporter layer was deposited by spin-coating from chlorobenzene at a concentration of 180 mg/mL, along with tert-butylpyridine (0.9 molar ratio to Spiro-OMeTAD) and Lithium-TFSI (0.14 molar ratio to Spiro-OMeTAD) additives. The films were left for a minimum period of 4 hours in air before placing them in a thermal evaporator where 200 nm thick silver electrodes were deposited through a shadow mask under high vacuum (10⁻⁶ mbar). The active area of the devices was defined by a metal optical mask with 0.11 cm² aperture.

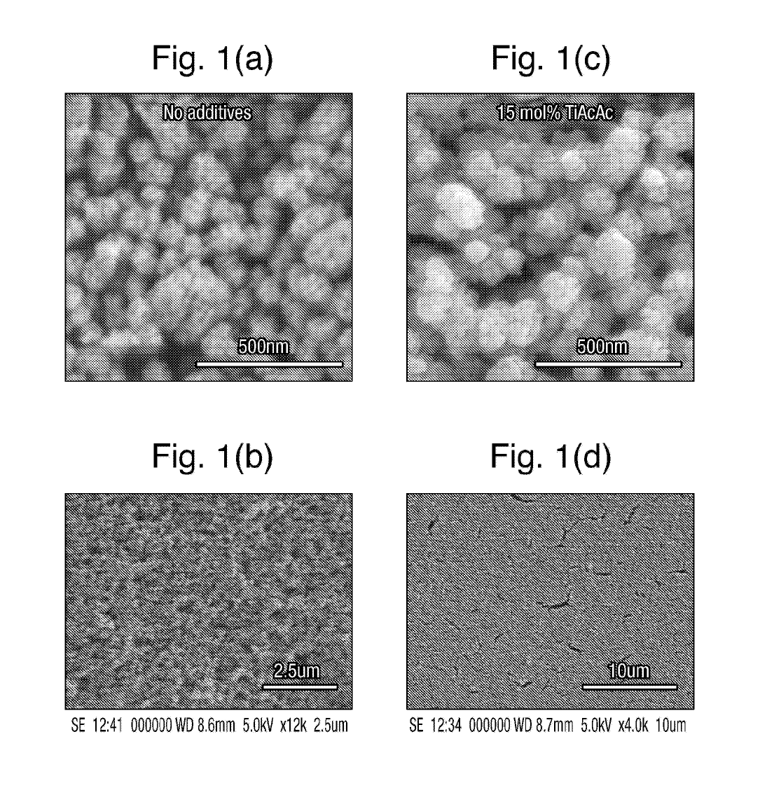

MSC film ensembles of MSCs deposited both with and without 15 mol % titanium diisopropoxide bis(acetylacetonate) additive are shown in FIG. 1. The effect of the titanium diisopropoxide bis(acetylacetonate) additive is clearly visible as a coating of the MSC pore surface. Films deposited with the additive have significantly improved mechanical stability (scratch resistant) compared to the neat MSC ensembles.

Dye-sensitized solar cells based on 150° C. processed MSC film ensembles of TiO₂ MSCs are shown in FIG. 2. FIG. 2(c) shows current-voltage curves measured under simulated AM1.5 100 mWcm⁻² sunlight for sub-150° C. processed SSCs employing the organic dye sensitizer D102 or a mixed-halide organometallic perovskite sensitizer, CH₃NH₃PbI₂Cl. The dye-sensitised cell achieves a 3% power conversion efficiency (PCE), comparable to the highest reported value of 4.1% for high temperature processed, D102-sensitized anatase nanoparticles and vastly greater than the previous best low temperature all-solid-state SSC. MSCs coupled with the more effective perovskite light harvester, deliver double the current and a PCE of over 7%, higher than any reported low-temperature SSC architecture and competitive with high-temperature devices.

FIG. 3 shows transient short-circuit photocurrent decay lifetimes for two device architectures based on 20 nm TiO₂ nanoparticles sintered on-film at 500° C. with polymer binder (commercially-available Dyesol 18NR-T) and MSCs with 15 mol % TiAcAc additive dried on film at 150° C. Charge extraction times are rapid in the 150° C. MSC film without the need for high temperature on-film sintering treatment.

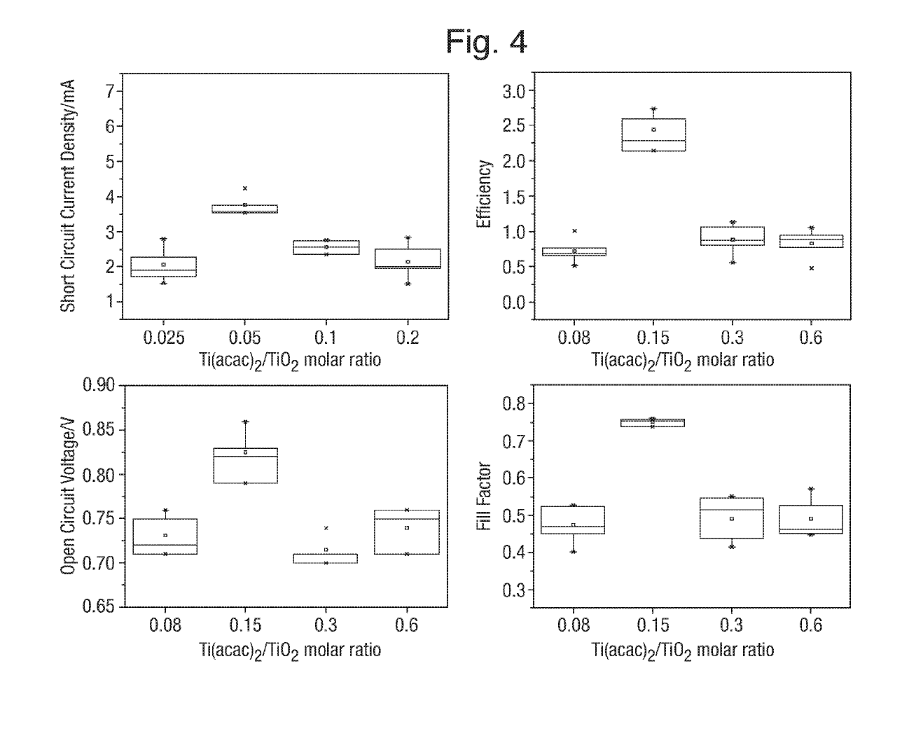

FIG. 4 shows the effect of TiAcAc additive ratio relative to TiO₂ present in MSCs on the primary performance parameters in organic dye-sensitized solar cells.

### Compact Layer Production

### Low Temperature Compact Layer Production

Unless otherwise stated, all materials were purchased from Sigma-Aldrich or Alfa Aesar and used as received. Spiro-OMeTAD was purchased from Borun Chemicals and used as received. The synthesis of the perovskite, CH₃NH₃PbI₃₋ₓClₓ has been reported elsewhere (M. M. Lee et al., Science, 2012, 338, 634-647). TiO₂ nanoparticles were synthesized by the following method. In a typical synthesis, 2 ml of anhydrous TiCl₄ (99.9%) was added dropwise, while stirring, into a vial containing 8 ml of anhydrous ethanol. The whole content was transferred into a 100 ml flask containing 40 ml anhydrous benzyl alcohol. The solution was heated to 80° C. and reacted for 9 hours. After that time, reaction was stopped by cooling down the solution, which contained a translucent dispersion of very fine TiO₂ nanoparticles. Then, 4 ml of the above solution was mixed with 36 ml of diethyl ether causing precipitation of the TiO₂. The powder was centrifuged, washed in acetone and redispersed in anhydrous ethanol, resulting in a colloidal solution of 28 mg TiO₂/ml (3.54 wt. % of TiO₂). The formulation was finalised by diluting the above solution 3 times (1.18 wt. % of TiO₂) in anhydrous ethanol and adding the right amount of TiAcAc (10-20 mol % in respect to TiO₂ The low temperature TiO₂ compact layer (lt-TiO₂) was prepared by spin-coating the colloidal dispersion of anatase particles in anhydrous ethanol, formulated with TiAcAc, followed by drying at 150° C. for 30 minutes. The thickness of the compact layer was tuned by the concentration of TiO₂ nanoparticles (3.54-0.24 wt. % TiO₂). As a control, a blocking layer of non-crystalline titania (TiOₓ) and high temperature-processed TiO₂ (ht-TiO₂) was used. The former was prepared by spin-coating a precursor solution (titanium isopropoxide, TTIP) in anhydrous ethanol (0.254 M), followed by annealing at 150° C. for 30 min, the latter was prepared by spin-coating the same solution (TTIP), followed by annealing at 150° C. and sintering at 500° C.

### Device Construction

Photovoltaic devices were fabricated on fluorine-doped tin oxide (FTO) coated glass (Pilkington, TEC7). Substrates were cleaned in hallmanex, then 10 minutes sonication in acetone, 10 minutes sonication in IPA, and 10 minutes of oxygen plasma etching. Compact layers were deposited by spin-coating, as described above. An alumina scaffold was deposited according to the previously reported method which employs Al₂O₃ nanoparticles of 20 nm in diameter. The photoactive layer was deposited in an inert atmosphere. After depositing the alumina scaffold samples were transferred into a nitrogen-filled glovebox, and the precursor solution of the concentration of 400 mg/ml (CH₃NH₃I and PbCl2, 3:1 molar ratio in dimethylformamide (DMF)) was spin-coated at room temperature, followed by annealing at 100° C. for 90 minutes. The hole transporter was deposited by spin-coating an 8 wt. % 2,2′,7,7′-tetrakis-(N,N-di-pmethoxyphenylamine)9,9-spirobifluorene (spiro-OMeTAD) in chlorobenzene with added tert-butylpiridine (tBP) and lithium bis(trifluoromethanesulfonyl)imide (Li-TFSI) of 80 and 30 mol %, with respect to spiro-OMeTAD. Finally, 150 nm thick silver electrodes were deposited on top of devices by thermal evaporation at ˜10⁻⁶ bar, through a shadow mask.

### Characterization Techniques

UV-Vis absorption spectra were obtained using a Carry 300 Bio (Agilent Technologies) spectrometer. Scanning Electron Microscopy images were obtained from Hitachi S-4300 Conductivity measurements of TiO₂ films were performed by evaporating gold electrodes through the shadow mask on the spin-coated compact layers and using 4-point probe set up with a Keithley 2400 as a sourcemeter. The electrode pattern was designed for 4-point probe measurements with an outer probe channel dimensions of 1 mm (length)×1 (width) and an inner probe separation of 300 μm. The thickness of the channel (TiO₂ was determined from SEM cross-sectional image. X-ray diffraction spectra were obtained from powder samples (the nanoparticle solution was dried in air at 150° C.) using Panalytical X'Pert Pro X-ray diffractometer. Current voltage characteristics of solar cells were measured under simulated AM1.5 100 mW·cm² sunlight (ABET Technologies Sun 2000) with a Keithley 2400 sourcemeter. The lamp was calibrated with an NREL-calibrated KG5 filtered silicon reference. The active area of the device was defined by a metal mask with square aperture of the area of 0.0625 cm². The pre-masked active area of the solar cells was approximately 0.12 cm² nominally defined by the overlap area of the silver and FTO electrodes. Solar cells were masked for all the current voltage measurements.

### Results and Discussion

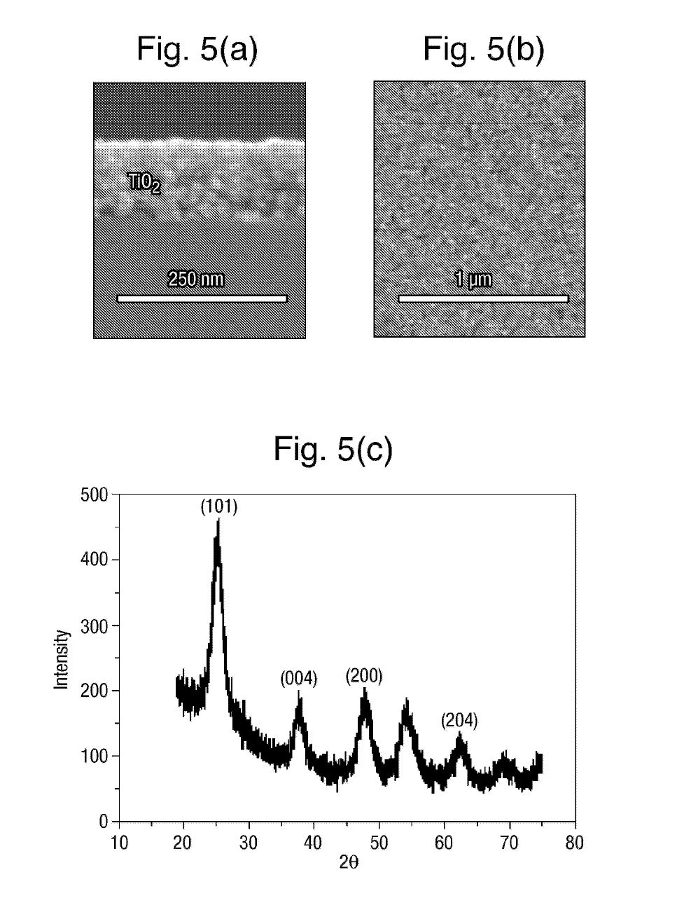

In this Example, the TiO₂ compact layer produced by the process according to the invention, which may be referred to as “low temperature TiO_{2″} (lt-TiO₂), is compared with a method used in MSSCs in which a solution of titanium isopropoxide in acidic ethanol is spin-coated upon the substrate (as described herein and referred to as “TiOₓ”). Comparison is also made with compact layers produced by sintering films of amorphous titania (TiOₓ) at 500° C. as is the current state-of-the-art (which may be referred to as ht-TiO₂). Here, the inventors synthesised TiO₂ nanoparticles by a nonaqueous route from benzyl alcohol. The X-ray diffraction spectrum of a powdered sample was measured, shown in FIG. 5(c), which can be assigned to anatase TiO₂ with a crystal diameter of 4.5 nm, as determined by Scherrer peak width analysis. FIGS. 5(a) and 5(b) show SEM images of the deposited nanoparticles.

The impact of varying the concentration of TiAcAc from a 0% to 80 mol % with respect to TiO₂ upon the conductivity of the films was also investigated, and compared to the TiOₓ and ht-TiO₂ routes. The results are shown in Table 1 and demonstrate that TiOₓ has a lower conductance. Remarkably, even the TiO₂ sol (i.e. no binder) shows a 50-fold increase in conductivity over the ht-TiO₂ and with the addition of a small amount of TiAcAc this increases to maximum of just below 10⁻³ Scm⁻¹. This demonstrates that at least as far as conductivity and series resistance are concerned, the new low temperature TiO₂ compact layer is better than the previous state of the art.

TABLE 1
Conductivity values of different blocking layers.

| | | Calculated Resistance |
|---|---|---|
| | Conductivity | through 100 nm thick film |
| Blocking layer | (S · cm⁻¹) | (0.12 cm² device area) |
| TiOₓ | 0.02 · 10⁻⁴ | 41.67 |
| ht-TiO₂ | 0.11 · 10⁻⁴ | 7.58 |
| lt-TiO₂ | 5.08 · 10⁻⁴ | 0.16 |
| (0 mol % TiAcAc) | | |
| lt-TiO₂ | 8.32 · 10⁻⁴ | 0.10 |
| (10 mol % TiAcAc) | | |
| lt-TiO₂ | 6.80 · 10⁻⁴ | 0.12 |
| (20 mol % TiAcAc) | | |
| lt-TiO₂ | 4.15 · 10⁻⁴ | 0.20 |
| (40 mol % TiAcAc) | | |
| lt-TiO₂ | 0.24 · 10⁻⁴ | 3.47 |
| (80 mol % TiAcAc) | | |

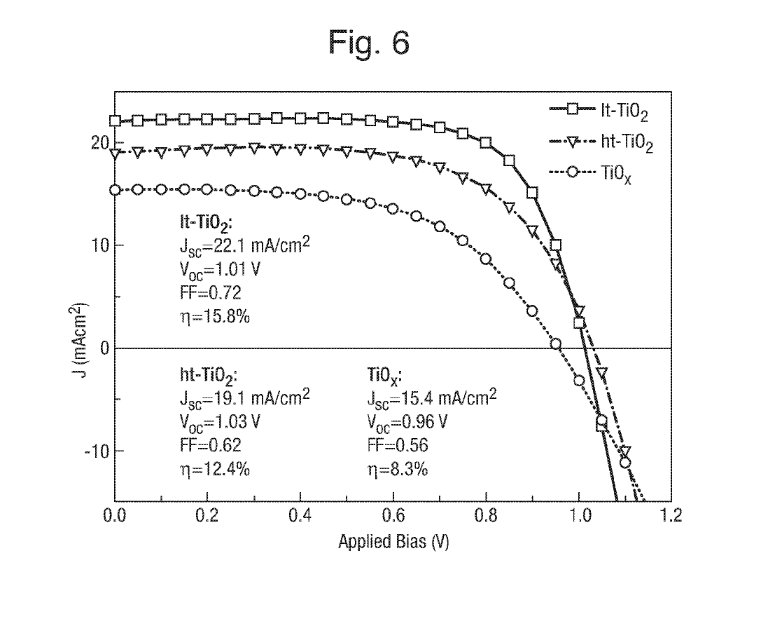

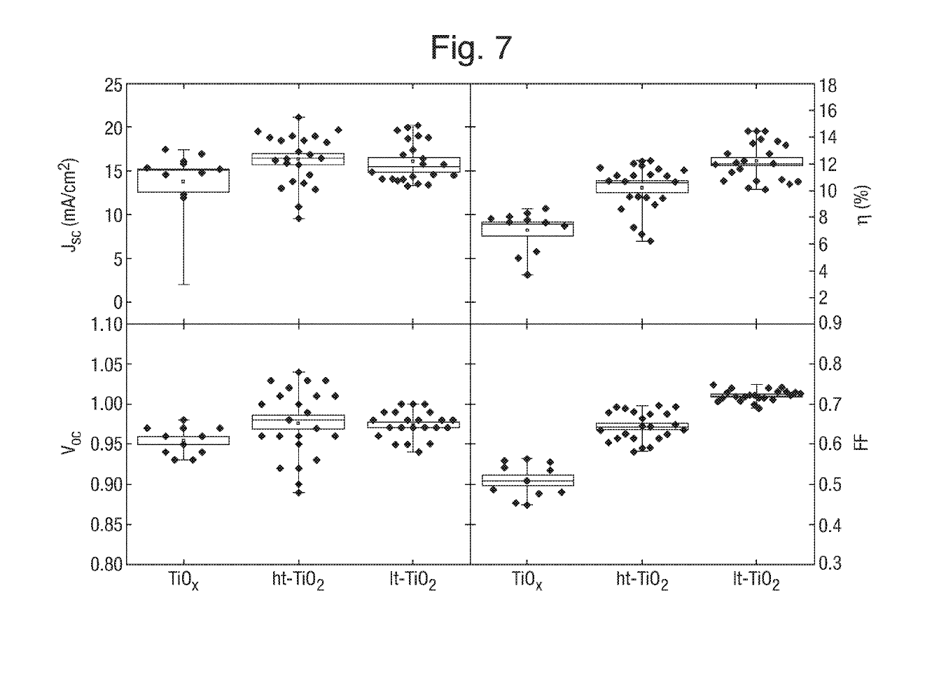

These films were incorporated into complete MSSCs. The optimum concentration of the binder for performance was 20 mol %. For the given TiO₂/TiAcAc molar ratio that yielded the best results in the preliminary trials (11.5:1) the thickness of the film was optimized by varying the concentration of nanoparticles. The optimum thickness was found to be 45 nm. A series of devices employing an optimised low temperature-processed TiO₂ formulation (lt-TiO₂) were fabricated and compared with devices employing high temperature-processed TiO₂ (ht-TiO₂) and amorphous titania (TiOₓ). The data is shown in FIGS. 6 and 7. The solar cell performance parameters, along with the solar cell series resistance determined by fitting the best JV curves to an ideal diode model, are shown in Table 2. Devices with the optimum low temperature processed compact layer surpass the performance of previous state-of-the-art sintered compact layer devices, delivering a maximum power conversion efficiency of 15.8%. The improvement is mainly due to higher fill factor, which rises above 0.7 in the best devices, consistent with the reduced series resistance in the solar cell.

TABLE 2
Photovoltaic parameters extracted from current-voltage
measurements of devices with different compact layers.

| Compact layer | | | | | |
|---|---|---|---|---|---|
| (mean ± s.d.) | J_{sc} (mA · cm⁻²) | η(%) | V_{OC} (V) | FF | Rₛ (Ω) |
| TiOₓ | 13.85 ± 4.30 | 7.03 ± 1.59 | 0.95 ± 0.02 | 0.51 ± 0.04 | 15.47 |
| ht-TiO₂ | 16.33 ± 2.98 | 10.22 ± 1.74 | 0.98 ± 0.04 | 0.64 ± 0.04 | 8.78 |
| lt-TiO₂ | 16.06 ± 2.37 | 12.18 ± 1.46 | 0.97 ± 0.02 | 0.72 ± 0.01 | 5.03 |
| (20 mol % TiAcAc) | | | | | |

The new low temperature processed compact TiO₂ is of higher conductivity than the known sintered (500° C.) material, and this delivers reduced overall series resistance in the perovskite solar cells. It appears that this isn't offset by faster recombination nor a less favourable band offset, which may be inferred from the invariance in the open-circuit voltage. At first sight this observation may be surprising, since in solid-state dye-sensitized solar cells, the series resistance at open-circuit is limited by hole-conduction through spiro-OMeTAD. However, here the spiro-OMeTAD is simply a solid capping layer (˜250 nm thick as opposed to 2 μm in the dye-sensitized solar cells) with a conductivity of close to 3×10⁻⁵ Scm⁻¹. Hence the overall series resistance expected through a 250 nm thick film with a surface area of 0.12 cm⁻² unmasked active area of the solar cell), is 7Ω. As shown in Table 1, the original high temperature processed TiO₂ compact layer is more resistive, and was contributing more to the series resistance of the solar cell than the spiro-OMeTAD.

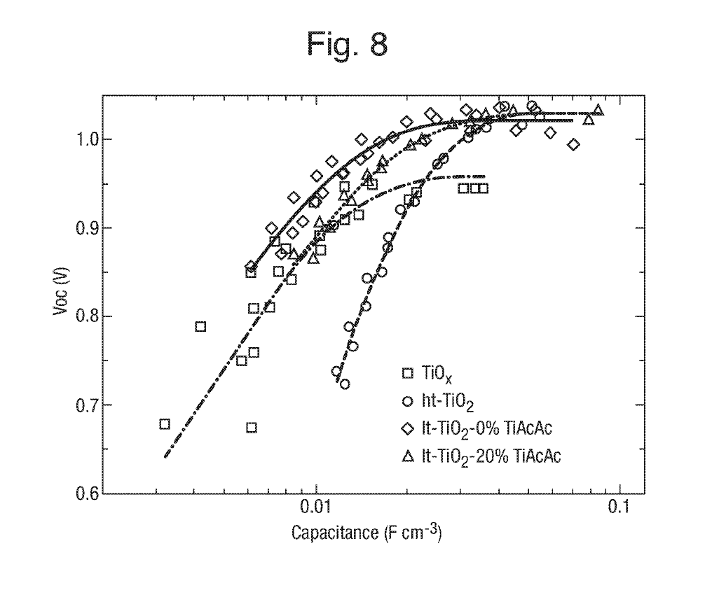

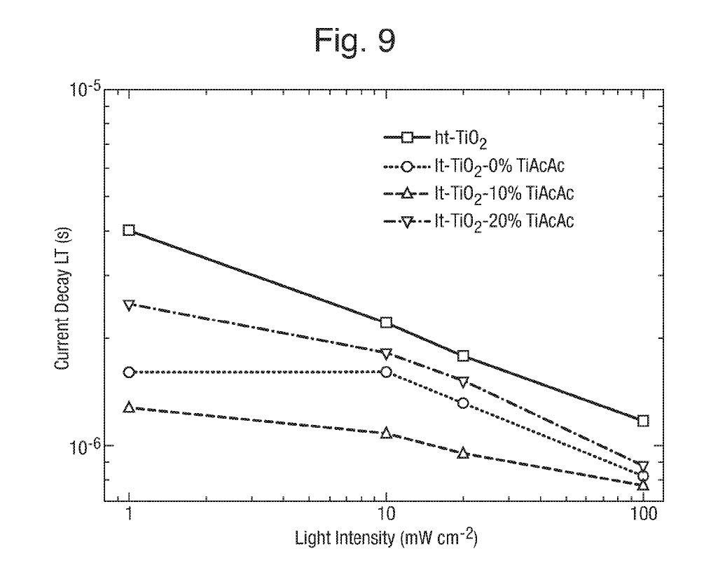

To probe the origin of the enhanced conductivity of the compact lt-TiO₂, small perturbation transient photovoltage and photocurrent decay measurements were performed, from which the differential capacitance of the solar cell can be determined. This is usually employed to probe the chemical capacitance of mesoporous TiO₂, with the differential capacitance being interpreted to reflect the density of states in the tail of the TiO₂ conduction band. Here, it is used to probe any changes which may occur due to the compact TiO₂ layer. In FIG. 8 it is shown that the differential capacitance as a function of voltage is considerably different for the devices with the different compact layers. Devices with ht-TiO₂ show much broader distribution of states than cells with lt-TiCO₂, suggesting significant reduction in sub-band gap states in the low temperature processed films. This is consistent with a higher mobility for electrons in the low temperature processed TiO₂, assuming that the electron transport in this layer proceeds via the multiple trapping framework. From short-circuit photocurrent decay measurements, a “charge collection lifetime” can be extracted, which represents how quickly charge flows out of the solar cell. It is shown in FIG. 9 that the charge collection gets faster with the lt-TiO₂, consistent with the inferred enhanced mobility in the compact TiO₂.

1. A process for producing a layer of a semiconductor material, wherein the process comprises:
a) disposing on a substrate
i) a plurality of particles of a semiconductor material,
ii) a binder, wherein the binder is a molecular compound comprising at least one metal atom or metalloid atom, and
iii) a solvent; and
b) removing the solvent;
wherein either the layer of a semiconductor material is a compact layer of the semiconductor material and the particles of the semi conductor material are then nanoparticles of the semiconductor material, or the layer of a semiconductor material is a mesoporous layer of the semiconductor material and particles of the semiconductor material then comprise mesoporous particles of the semiconductor material.

2. The process according to claim 1 wherein the process is carried out at a temperature less than or equal to 300° C., preferably at a temperature less than or equal to 200° C., and more preferably at a temperature less than or equal to 150° C.

3. The process according to claim 1 wherein the binder is any of:
i) a molecular compound comprising at least one metal or metalloid atom and one or more atoms selected from O, S, Se and Te;
ii) a molecular compound comprising at least one metal or metalloid atom and one or more groups of formula XR, wherein
each X is the same or different and is an atom selected from O, S, Se and Te; and
each R is the same or different and is an unsubstituted or substituted C₁-C₈ hydrocarbyl group, and wherein two or more R groups may be bonded to each other;
iii) a molecular compound with the formula [MₐY_{b}(XR)_{c}Z_{d}] wherein:
each M is the same or different and is a metal atom or a metalloid atom;
each X is fee same or different and is an atom selected from Q, S, Se, and Te;
each Y is the same or different and is an atom selected from Q, S, Se, and Te;
each Z is the same or different and is a monodentate group;
each R is the same or different and is an unsubstituted or substituted C₁-C₈ hydrocarbyl group, wherein two or more R groups may be bonded to each other;
a is an integer from 1 to 4;
b is 0 or an integer from 1 to 7;
c is an integer from 1 to 16;
d is 0 or an integer from 1 to, 15; and
2b+c+d is less than or equal to the total valence of the one or more M atoms;
iv) a molecular compound with the formula [MO_{c}(OR)_{f}] wherein:
M is a metal atom or a metalloid atom;
each R is the same or different and is an unsubstituted or substituted C₁-C₈ hydrocarbyl group, wherein two or more R groups maybe bonded to each other;
e is 0 or an integer from 1 to 3;
f is an integer from 1 to 8; and
2e+f is equal to the valence of M; and
v) a molecular compound of formula (1) 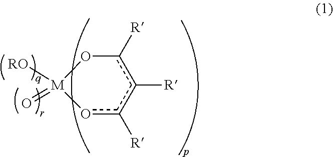
wherein
M is a metal atom or a metalloid atom;
each R is the same or different and k an unsubstituted or substituted C₁-C₈ hydrocarbyl group, wherein two or more R groups may be bonded to each other;
each R′ is the same or different and is H or an unsubstituted or substituted C₁-C₃ hydrocarbyl group, wherein two or more R′ groups may be bonded to each other;
p is an integer from 1 to 4;
q is 0 or an integer from 1 to 6;
r is 0 or an integer from 1 to 3; and
2p+q+2r is equal Jo the valence of M.

4. (canceled)

5. A process according to claim 1 comprises:
a) disposing on the substrate
i) a first composition comprising the plurality of particles of a semiconductor material, and
ii) a second composition comprising the binder,
wherein at least one of the first and the second composition also comprises the solvent; and
b) removing the solvent;
preferably wherein the first composition further comprises the solvent which is a first solvent, and the second composition further comprises a second solvent, wherein the first and second solvents are the same or different and where step b) comprises removing the first and second solvents,
preferably wherein the first composition comprises the plurality of particles of a semiconductor material dispersed in the first solvent and the second composition comprises the binder dissolved in the second solvent.

6. (canceled)

7. A process according to claim 1 which comprises:
a) disposing on the substrate a composition comprising the solvent, the binder and the plurality of particles of a semiconductor material; and
b) removing the solvent;
preferably wherein the plurality of particles of a semiconductor material are suspended or dispersed in the solvent and the binder is dissolved in the solvent.

8. (canceled)

9. A process according to claim 1 wherein the amount of the plurality of particles of a semiconductor material present is from 0.05 to 20 wt %, and the amount of the binder is from 5 to 40 mol % relative to the amount of the semiconductor material.

10. (canceled)

11. A process according to claim 1 wherein the solvent is an organic solvent or, if first and second solvents are present, the first solvent is an organic solvent, the second solvent is an organic solvent, or both the first and second solvents are organic solvents;
preferably wherein the solvent or solvents are selected from an alcohol, a thiol, an ether, a ketone, an aldehyde, an alkane, a cycloalkane, an aromatic hydrocarbon, a heterocyclic compound, an aromatic heterocyclic compound, a halogenated hydrocarbon, or an amine;
optionally wherein the solvent or solvents are selected from methanol, ethanol, propanol, isopropanol, butanol, secbutanol, or tertbutanol.

12-13. (canceled)

14. A process according to claim 1 wherein the solvent is water or, if first and second solvents are present, the first solvent is water, the second solvent is water or both the first and second solvents are water.

15-21. (canceled)

22. A process according to claim 1 wherein the binder is selected from: titanium di(C₁-C₈-alkoxide) bis(acetylacetonate); niobium ethoxide; a metal compound comprising an acetylacetonate group, wherein the metal is selected from titanium, zirconium, vanadium, niobium, chromium, molybdenum, tungsten, manganese, rhenium, iron, ruthenium, osmium, cobalt, rhodium, iridium, nickel, palladium, platinum, copper, zinc and aluminium; tetra(C₁-C₈-hydrocarbyl) orthosilicates; and tri(C₁-C₈-hydrocarbyl) borates;
preferably wherein fee binder is selected from titanium di-isopropoxide bis(acetylacetonate), vanadium acetylacetonate, niobium ethoxide, and tetraethyl orthosilicate.

23-24. (canceled)

25. A process according to claim 1 wherein the layer of a semiconductor material is a compact layer of the semiconductor material and the compact layer of the semiconductor material is a layer without open porosity;
preferably wherein the compact layer of a semiconductor material is substantially non-porous; and
optionally wherein the compact layer of the semiconductor material has a thickness of from 5 to 500 nm.

26-30. (canceled)

31. A process according to claim 1 wherein the particles of a semiconductor material are nanoparticles of the semiconductor material and wherein the of the semiconductor material are crystalline;
optionally wherein the nanoparticles of a semiconductor material have an average particle size of less than or equal to 10 nm; and
optionally wherein the particles of a semiconductor material are nanoparticles of anatase TiO₂.

32-35. (canceled)

36. A process according to claim 1 wherein the layer of a semiconductor material is a compact layer of the semiconductor material and wherein the amount of the plurality of particles of the semiconductor material Is from 0.05 to 5 wt %; and optionally wherein the amount of the hinder is from 1 to 40 mol %. preferably from 5 to 35 mol %. relative to the amount of fee semiconductor material.

37-44. (canceled)

45. A process according to claim 1 wherein the particles of a semiconductor material comprise mesoporous particles of the semiconductor material wherein the mesoporous particles comprise any of:
an assembly of nanocrystals of the semiconductor material; and
mesoporous single crystals of the semiconductor material, optionally wherein the shortest external dimension of each of said mesoporous single crystal, measured along any of the crystallographic principle axes of the crystal, is greater than or equal to 50 nm; and optionally wherein the volume of each of said mesoporous single crystal is greater than or equal to 1.25×10⁵ nm³.

46-49. (canceled)

50. A process according to claim 1 wherein the particles of a semiconductor material comprise: an oxide or chalcogenide of a metal or metalloid element; a group IV compound; a compound comprising a group III element and a group V element; a compound comprising a group II element and a group VI element; a compound comprising a group I element and a group VII element; a compound comprising a group IV element and a group VI element; a compound comprising a group V element and a group VI element; a compound comprising a group II element and a group V element; a ternary or quaternary compound semiconductor; a perovskite; or an organic semiconductor;
preferably wherein the particles of a semiconductor material comprise an oxide of titanium, niobium, tin, zinc, cadmium, copper or lead or a mixed oxide of combination of one or more of said metals; a chalcogenide of antimony, bismuth or cadmium or a mixed chalcogenide of any combination of one or more of said metals: zinc tin oxide; cooper zinc tin sulphide; cooper zinc tin selenide; copper indium gallium selenide; copper indium gallium diselenide; or copper zinc tin selenide sulphide;
more preferably wherein the particles of a semiconductor material comprise, titanium dioxide; and
yet more preferably wherein the particles of a semiconductor material comprise anatase or rutile titanium dioxide.

51-55. (canceled)

56. A process according to claim 1 wherein:
the binder comprises titanium di-isopropoxide bis(acetylacetonate) and the semiconductor material comprises titanium dioxide;
the binder comprises vanadium acetylacetonate and the semiconductor material comprises titanium dioxide;
the binder comprises niobium ethoxide and the semiconductor material comprises titanium dioxide;
the binder comprises titanium di-isopropoxide bis(acetylacetonate) and the semiconductor material comprises zinc oxide;
the binder comprises titanium di-isopropoxide bis(acetylacetonate) and the semiconductor material comprises tin oxide;
the binder comprises tetraethyl orthosilicate and the semiconductor material comprises tin oxide;
the binder comprises tetraethyl orthosilicate and the semiconductor material comprises silicon; or
the binder comprises cadmium chloride and the semiconductor material comprises cadmium telluride.

57-58. (canceled)

59. A process according to claim 45 which comprises disposing on the substrate a composition comprising the solvent, a plurality of mesoporous single crystals of titanium dioxide, and titanium di-isopropoxide bis(acetylacetonate), wherein the plurality of mesoporous single crystals of titanium dioxide are dispersed in the solvent and the titanium di-isopropoxide bis(acetylacetonate) is dissolved in the solvent; and
preferably wherein the composition contains from 1 to 20 wt % of said plurality of mesoporous single crystals of titanium dioxide and from 1 to 40 mol % of said titanium di-isopropoxide bis(acetylacetonate) relative to the amount of titanium dioxide.

60. (canceled)

61. A process according to claim 1 wherein:
the plurality of particles of a semiconductor material comprises a plurality of nanoparticles of anatase titanium dioxide; and
the binder comprises titanium di-isopropoxide bis(acetylacetonate);
optionally wherein the solvents is anhydrous ethanol; and
optionally wherein the process comprises disposing on the substrate a composition comprising the solvent, a plurality of nanoparticles of anatase titanium dioxide, and said titanium di-isopropoxide bis(acetylacetonate), wherein the plurality of nanoparticles of titanium dioxide are dispersed in the solvent and the titanium di-isopropoxide bis(acetylacetonate) is dissolved in the solvent, preferably wherein the composition contains from 0.05 to 5 wt % of said plurality of nanocrystals of anatase titanium dioxide and from 5 to 35 mol % of said titanium di-isopropoxide bis(acetylacetonate) relative to the amount of titanium dioxide.

62-64. (canceled)

65. A process according to claim 1 wherein the solvent is removed by allowing the solvent to evaporate, by heating or by vacuum evaporation;
preferably wherein the solvent is removed by heating, wherein the heating comprises heating the solvent at a temperature of from 100° C. to 200° C. or a temperature of less than or equal to 150° C.

66-104. (canceled)

105. A compact layer for a semiconductor device, which compact layer comprises a plurality of crystalline nanoparticles of a semiconductor material bound together by a decomposition product of a binder, wherein the binder is a molecular compound comprising at least one metal atom or metalloid atom.

106-107. (canceled)

108. A compact layer according to claim 105 wherein the decomposition product of the binder is amorphous;
preferably wherein the decomposition product of the binder is an amorphous form of a semiconductor;
more preferably wherein the decomposition product of a hinder is an amorphous form of the semiconductor material; and
yet more preferably wherein the particles of the semiconductor material are nanoparticles of anatase TiO₂ and the decomposition product of a binder is amorphous titania.

109-113. (canceled)

114. A compact layer according to claim 105 wherein the compact layer has a thickness of from 5 to 500 nm;
preferably wherein the compact layer is a layer without open porosity;
optionally wherein the compact layer is substantially non-porous; and
optionally wherein the compact layer has a conductivity of greater than or equal to 0.2*10⁻⁴ Scm⁻¹.

115-158. (canceled)
